(19) United States
(12) Patent Application Publication
(10) Pub. No.: US 2011/0169118 A1
(43) Pub. Date: Jul. 14, 2011

(54) OPTICAL DEVICE, METHOD OF MANUFACTURING THE SAME, AND ELECTRONIC APPARATUS

(75) Inventor: Hikari SANO, Hyogo (JP)

(73) Assignee: PANASONIC CORPORATION, Osaka (JP)

(21) Appl. No.: 13/004,354

(22) Filed: Jan. 11, 2011

(30) Foreign Application Priority Data
Jan. 13, 2010 (JP) 2010-005351

(51) Int. Cl. H01L 31/0232; H01L 31/18

(52) U.S. Cl. 257/432; 438/68; 257/E31.001; 257/E31.127

(57) ABSTRACT

The present invention is has an object of providing an optical device miniaturized while maintaining bonding strength between a semiconductor substrate and a light-transmissive plate, reducing possibility of warpage, and maintaining yields and design flexibility, a method of manufacturing the optical device, and an electronic apparatus. The optical device according to the present invention includes a semiconductor substrate having one surface in which a light-receiving element is formed; and a light-transmissive plate provided above the semiconductor substrate so as to cover the light-receiving element. The semiconductor substrate and the light-transmissive plate are partially bonded above a light-receiving unit of the semiconductor substrate. The light-receiving element is formed in the light-receiving unit.

### BACKGROUND OF THE INVENTION

(1) Field of the Invention

The present invention relates to optical devices on which semiconductor chips provided with optical elements are mounted, a method of manufacturing the optical devices, and electronic apparatuses. The optical devices include light-receiving elements such as a solid-state imaging device and a photo IC, and a light-emitting element such as a light-emitting diode (LED) and a laser element.

(2) Description of the Related Art

In recent years, for semiconductor devices which are for use in various electronic apparatuses, there is an increasing demand for miniaturization, reduction in thickness and weight, and packaging at higher density. Along with this, packaging techniques have been presented which allow ultra-small packaging at a size as small as a semiconductor chip, that is, chip-size packaging when used with semiconductor devices further highly integrated by advanced microprocessing.

For example, miniaturization and chip-size packaging of optical devices have been achieved by a technique. In the technique, an optical element is formed on a light-receiving surface of a semiconductor substrate, and the light-receiving surface is sealed with a light-transmissive substrate comparable in size to the semiconductor substrate while external electrodes are provided on the other surface of the semiconductor substrate. Such a technique for optical devices is disclosed in International Publication Pamphlet WO 2005/022631 (Patent Reference 1).

### SUMMARY OF THE INVENTION

The following describes a configuration of a solid-state imaging device as an example of optical devices including through electrodes with reference to sectional views shown in FIG. 26 and FIG. 27.

A solid-state imaging device shown in FIG. 26 includes a semiconductor substrate 101, a light-receiving unit (pixel unit) 102 including a plurality of light-receiving elements formed in one surface (top surface) of the semiconductor substrate 101, and microlenses 103 formed above the light-receiving unit 102. The semiconductor substrate 101 is bonded to a light-transmissive plate 104, which is comparable in size to the semiconductor substrate 101, with a bonding layer 105 provided in a peripheral part of the semiconductor substrate 101.

The solid-state imaging device is composed of through holes 107, an insulating film 108a, a conducting film 109a, and conductors 110a, and includes through electrodes 106 which electrically connects the one surface (top surface) and the other surface (bottom surface) of the semiconductor substrate. On the bottom surface of the semiconductor substrate 101, electrodes 111, each of which is composed of an insulating film 108b, a conducting film 109b, and a conductor 110b and electrically connected to a corresponding one of the through electrodes 106, are formed. A bottom surface of each of the electrode 111 except an external electrode part, which is a part where the electrode 111 is in contact with an external terminal 112, is covered with an insulating film 115. A top surface of the semiconductor substrate 101 except the part where the electrodes 111 are present is covered with an insulating film 113 composed of an interlayer insulating film 113a and a passivation film 113b.

A solid-state imaging device having such a structure as shown in FIG. 26 needs to be provided with a certain bonding region in a peripheral part of the semiconductor substrate 101 so that a certain degree of bonding strength is secured between the semiconductor substrate 101 and the light-transmissive plate 104. That is, above the one surface of the semiconductor substrate 101, the light-transmissive plate 104 is bonded to the semiconductor substrate 101 in the peripheral part thereof via the bonding layer 105, but the bonding region between the light-transmissive plate 104 and the semiconductor substrate 101 is limited to a surrounding region of the light-receiving unit 102 of the semiconductor substrate 101 because the bonding layer 105 has an opening across a region above the light-receiving unit 102 in which light-receiving elements are integrated. Because of this, in the case where such a certain bonding region is not secured on the semiconductor substrate 101, bonding strength may be insufficient so that resistance to moisture and impact may deteriorate.

In recent years in particular, as in the solid-state imaging device including the through electrode 106 as described above and a back-side illumination solid-state imaging device (for example, see Japanese Unexamined Patent Application Publication Number 2003-31785), miniaturization of solid-state imaging devices has been further advanced by reducing the surrounding region of the light-receiving unit 102 with external terminals 112 provided on a surface opposite to the surface in which the light-receiving unit 102 of the semiconductor substrate 101 is provided. However, such miniaturization is constrained by the necessity to secure a certain bonding region in a surrounding region of a light-receiving unit.

In addition, in the case of a solid-state imaging device having a hollow structure in which a space is provided between the semiconductor substrate 101 and the light-transmissive plate 104, the larger the ratio of the volume of the space to that of the solid-state imaging device is, the more likely the solid-state imaging device to have a warp. In particular, the solid-state imaging device including the through electrode 106 and the back-side illumination solid-state imaging device have been made so thin, their surrounding regions have been reduced so much, and the light-receiving units have been made so large that there is a possibility that characteristics of these devices are damaged by such warpage In addition, there is a possibility of constraint on fabrication of thinner solid-state imaging devices and increase in process steps because the semiconductor substrate 101 of the back-side illumination solid-state imaging device is polished to be so thin (approximately 5 to 15 micrometers) that the back-side illumination solid-state imaging device needs to be reinforced with a protective plate or the like. In addition, in a method of manufacturing a solid-state imaging device in which the semiconductor substrate 101 is thinned after bonding a large semiconductor substrate 101 and a large light-transmissive plate 104, polishing pressure at which the back side of the semiconductor substrate 101 is polished differs between the hollow region and the bonding region. As a result, the thickness of the polished semiconductor substrate 101 differs between the hollow region and the bonding region (occurrence of dishing), causing warpage in the semiconductor substrate 101, so that there is a possibility of damage to characteristics of the device and handling in processing.

The following describes another configuration of a solid-state imaging device with reference to FIG. 27.

In the solid-state imaging device shown in FIG. 27, a bonding layer 215 evenly covers a surface of a semiconductor substrate 101 in which a light-receiving unit 102 with light-receiving elements integrated therein is provided. The semiconductor substrate 101 is bonded to a light-transmissive plate 104 via the bonding layer 215.

In the solid-state imaging device having such a structure, a void may occur in the bonding layer 215 above the light-receiving unit 102 when the light-transmissive plate 104 and the semiconductor substrate 101 are bonded. In this case, characteristics of the solid-state imaging device are likely to be damaged by change in optical characteristics of the bonding layer 215 in the part where the void is present. In particular, there is a possibility that occurrence of a void reduces yields in a method of manufacturing solid-state imaging devices, where they are produced as final products by dicing, into unit structures each including the light-receiving unit 102, an intermediate product prepared by bonding a large light-transmissive plate 104 and the large scale semiconductor substrate 101 in which the unit structures are formed with regular intervals via a bonding layer 215, because a void may occur in the bonding of the large light-transmissive plate 104 and the large semiconductor substrate 101.

In addition, because the bonding layer 215 is required to have physical properties to provide satisfactory optical characteristics, the choice of materials for the bonding layer 215 is restricted. Therefore, the range of design options for solid-state imaging device is narrow. In particular, the bonding layer 215 is also required to have satisfactory process tolerance when a solid-state imaging device is manufactured using a method in which a large semiconductor substrate 101 and a large light-transmissive plate 104 bonded with a bonding layer 215 are passed on to backend processes on the semiconductor substrate 101 such as a thinning process and a wet process. Furthermore, there are many relevant technical problems. For example, considering light deterioration of the bonding layer, organic materials are not appropriate for the bonding layer of an optical device including a light-receiving element for shorter-wavelength light for use in a Blu-ray disc recorder and the like.

The present invention, conceived to address the problems, has an object of providing an optical device miniaturized while maintaining bonding strength between the semiconductor substrate and the light-transmissive plate, reducing possibility of warpage, and maintaining yields and design flexibility, a method of manufacturing the optical device, and an electronic apparatus.

In order to achieve the object, the optical device according to an aspect of the present invention includes: a semiconductor substrate having one surface in which an optical element is formed; and a light-transmissive plate provided above the semiconductor substrate so as to cover the optical element, wherein the semiconductor substrate and the light-transmissive plate are partially bonded above an element region of the semiconductor substrate, the element region being a region in which the optical element is formed.

Here, the optical device may include a bonding layer formed between the semiconductor substrate and the light-transmissive plate to bond the semiconductor substrate and the light-transmissive plate, wherein the bonding layer may include: a circumferential layer provided above a region surrounding the element region of the semiconductor substrate; and a pillar provided above the element region and apart from the circumferential layer.

In this configuration, the semiconductor substrate and the light-transmissive plate are bonded above the element region in which the optical element is formed, so that the area of the bonding region between the semiconductor substrate and the light-transmissive plate, surrounding the element region, may be reduced while the bonding strength between the semiconductor substrate and the light-transmissive plate is maintained. As a result, miniaturization of the optical device is achieved while maintaining bonding strength between the semiconductor substrate and the light-transmissive plate.

In addition, since the semiconductor substrate and the light-transmissive plate are bonded also in the element region, the hollow region between the semiconductor substrate and the light-transmissive plate are reduced. Thus, structural differences between the element region and the region surrounding the element region are minimized. As a result, possibility of warpage is reduced.

In addition, since the bonding between the semiconductor substrate and the light-transmissive plate in the element region is partial, the element region is unlikely to be influenced by a void occurred in the bonding layer. Thus, decrease in yields is prevented. At the same time, the position of the bonding in the element region may be adjusted so that the bonding is positioned outside effective optical regions of part of the optical elements. Thus, flexibility in the choice of a material for the bonding layer is maintained even when the bonding layer is interposed between the semiconductor substrate and the light-transmissive plate. As a result, deterioration in design flexibility is prevented.

The present invention thus provides a miniaturized optical device with maintained bonding strength between the semiconductor substrate and the light-transmissive plate and reduced possibility of warpage, while maintaining yields and design flexibility of the optical device.

Furthermore, an electronic apparatus according to an aspect of the present invention features the optical device incorporated therein.

The present invention thus allows miniaturization of an electronic apparatus in which bonding strength between a semiconductor substrate and a light-transmissive plate is maintained and the possibility of warpage of the semiconductor substrate is reduced, while maintaining yields and design flexibility of the electronic apparatus.

Furthermore, a method of manufacturing the optical device according to an aspect of the present invention includes: forming optical elements in a semiconductor substrate in a manner such that the optical elements are arranged on both sides of a scribe region of the semiconductor substrate; bonding the semiconductor substrate and a light-transmissive plate; and dicing the semiconductor substrate in the scribe region, wherein, in the bonding, the semiconductor substrate and the light-transmissive plate are partially bonded above an element region in which the optical elements in the semiconductor substrate are formed.

The present invention thus provides a method of manufacturing a miniaturized optical device with maintained bonding strength between the semiconductor substrate and the light-transmissive plate and reduced possibility of warpage, while maintaining yields and design flexibility of the optical device.

The present invention thus provides a miniaturized optical device with maintained bonding strength between the semiconductor substrate and the light-transmissive plate and reduced possibility of warpage while maintaining yields and design flexibility of the optical device, a method of manufacturing the same, and an electronic apparatus. As a result, the optical device and electronic apparatus provided are small in size and provide high productivity and improved performance with high reliability, and a method of manufacturing such an optical device is provided.

The present invention is therefore applicable to optical devices mounted with a chip including a light-transmissive plate comparable in size to a semiconductor substrate in the chip, such as optical devices typified by light-receiving and -emitting devices and solid-state imaging devices having through electrodes, and back-side illumination optical devices, as well as to electronic apparatuses in which such optical devices are used.

### FURTHER INFORMATION ABOUT TECHNICAL BACKGROUND TO THIS APPLICATION

The disclosure of Japanese Patent Application No. 2010-005351 filed on Jan. 13, 2010 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a perspective view of a solid-state imaging device according to Embodiment 1 of the present invention;

FIG. 2 is a plan view of the solid-state imaging device according to Embodiment 1 of the present invention;

FIG. 3 is a sectional view of the solid-state imaging device according to Embodiment 1 of the present invention;

FIG. 4A is a part sectional view of the solid-state imaging device according to Embodiment 1 of the present invention;

FIG. 4B is a part plan view of the solid-state imaging device according to Embodiment 1 of the present invention;

FIG. 5 is a part sectional view illustrating a method of the solid-state imaging device according to Embodiment 1 of the present invention;

FIG. 6 is a part sectional view illustrating the method of the solid-state imaging device according to Embodiment 1 of the present invention;

FIG. 7 is a part sectional view illustrating the method of the solid-state imaging device according to Embodiment 1 of the present invention;

FIG. 8 is a part sectional view illustrating the method of the solid-state imaging device according to Embodiment 1 of the present invention;

FIG. 9 is a part sectional view illustrating the method of the solid-state imaging device according to Embodiment 1 of the present invention;

FIG. 10 is a part sectional view illustrating the method of the solid-state imaging device according to Embodiment 1 of the present invention;

FIG. 11 is a part sectional view illustrating the method of the solid-state imaging device according to Embodiment 1 of the present invention;

FIG. 12 is a part sectional view illustrating the method of the solid-state imaging device according to Embodiment 1 of the present invention;

FIG. 13 is a part sectional view illustrating the method of the solid-state imaging device according to Embodiment 1 of the present invention;

FIG. 14 is a part sectional view illustrating the method of the solid-state imaging device according to Embodiment 1 of the present invention;

FIG. 15 is a part sectional view illustrating the method of the solid-state imaging device according to Embodiment 1 of the present invention;

FIG. 16 is a sectional view illustrating a mounting configuration of the solid-state imaging device according to Embodiment 1 of the present invention;

FIG. 17 is a part sectional view of the solid-state imaging device according to Embodiment 1 of the present invention;

FIG. 18 is a part plan view of the solid-state imaging device according to Embodiment 1 of the present invention;

FIG. 19 is a part plane view of the solid-state imaging device according to Embodiment 1 of the present invention;

FIG. 20 is a part sectional view of the solid-state imaging device according to Embodiment 1 of the present invention;

FIG. 21A is a plan view of the solid-state imaging device according to Embodiment 1 of the present invention;

FIG. 21B is a plan view of the solid-state imaging device according to Embodiment 1 of the present invention;

FIG. 22 is a sectional view of the solid-state imaging device according to Embodiment 2 of the present invention;

FIG. 23A is a sectional view of the solid-state imaging device according to Embodiment 3 of the present invention;

FIG. 23B is a sectional view of the solid-state imaging device according to Embodiment 3 of the present invention;

FIG. 23C is a sectional view of the solid-state imaging device according to Embodiment 4 of the present invention;

FIG. 24A is a plan view of a light-receiving and -emitting device according to Embodiment 5 of the present invention;

FIG. 24B is a sectional view of a light-receiving and -emitting device according to Embodiment 5 of the present invention;

FIG. 25A shows a configuration of an optical apparatus according to Embodiment 6 of the present invention;

FIG. 25B shows a configuration of an optical apparatus according to Embodiment 6 of the present invention;

FIG. 26 is a sectional view of a solid-state imaging device; and

FIG. 27 is a sectional view of a solid-state imaging device.

### DESCRIPTION OF THE PREFERRED EMBODIMENTS

The following describes exemplary embodiments of the present invention with reference to the drawings. The same components are provided with the same reference numerals in the drawings and briefly described. The drawings mainly show features of the present invention, and detailed descriptions and drawings of structures of devices, such as elements and circuits, and methods of manufacturing them are omitted as long as they are the same as conventional techniques. The position relations between components according to the present invention are not limited to the drawings, and the following describes the position relations according to the drawings for simplification.

### Embodiment 1

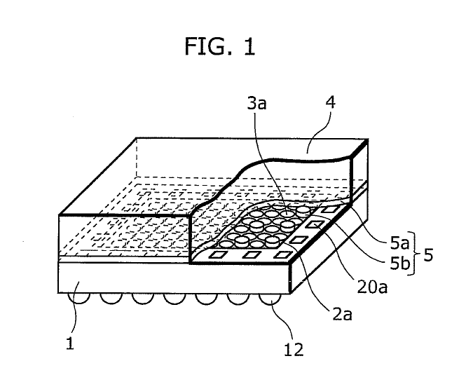

FIG. 1 to FIG. 3 show a structure of a CMOS solid-state imaging device which is a typical optical device according to Embodiment 1 of the present invention, and are respectively a perspective view, a plan view, and a sectional view illustrating the CMOS solid-state imaging device.

As shown in FIG. 1 to FIG. 3, the solid-state imaging device according to Embodiment 1 is a solid-state imaging device having through electrodes. In the solid-state imaging device, in semiconductor processing, a light-receiving unit (pixel unit) 2a including one or more unit pixels (not shown) is formed in one surface (top surface) of a semiconductor substrate 1, and peripheral circuitry (not shown) is formed in a peripheral part of the semiconductor substrate 1 through semiconductor processes. Each of the unit pixels includes light-receiving elements (not shown), which is an optical element, and one or more active elements (not shown). The peripheral circuitry includes a circuit mainly for controlling driving of elements in the unit pixels and a circuit for processing input and output signals to and from the unit pixels.

The top surface of the semiconductor substrate 1 is covered with a light-transmissive plate 4 fixed to the semiconductor substrate 1 via a bonding layer 5 described below. The light-receiving elements formed in the top surface of the semiconductor substrate 1 are covered with the light-transmissive plate 4 provided above the semiconductor substrate 1. The light-transmissive plate 4 is preferably comparable in size to the semiconductor substrate 1 to secure a bonding region to the bonding layer 5. The light-transmissive plate 4 is provided in order to prevent dust on a top surface of the light-receiving unit 2a from being captured in a picture or to reinforce the semiconductor substrate 1 for processing and handling. The light-transmissive plate 4 may be provided with an optical filter on one or each of its top surface and bottom surfaces. The optical filter is provided in order to add optical characteristics, such as anti-reflection and wavelength cutoff, to the light-transmissive plate 4 as necessary.

The semiconductor substrate 1 and the light-transmissive plate 4 are partially bonded to each other in a manner such that a space is formed between the semiconductor substrate 1 and the light-transmissive plate 4 and above the light-receiving unit 2a, which is an element region of the semiconductor substrate 1 and a region in which the light-receiving elements are formed. The bonding layer 5 is formed between the semiconductor substrate 1 and the light-transmissive plate 4 and bonds the semiconductor substrate 1 and the light-transmissive plate 4. The bonding layer 5 includes a circumferential layer 5a provided above a region surrounding the light-receiving unit 2a in the top surface of the semiconductor substrate 1, and pillars 5b provided above the light-receiving unit 2a and apart from the circumferential layer 5a. The pillars 5b are provided only in light-receiving regions, which are effective optical regions, of part of the light-receiving elements, and provided in positions outside the light-receiving regions of the rest of the light-receiving elements.

In addition, as shown in FIG. 3, electrodes 20a are formed in the peripheral part of the semiconductor substrate 1, and the top surface of the semiconductor substrate 1 is covered with an insulating film 13 including one or more stacked films. In the insulating film 13, wiring (not shown) is formed in semiconductor processing. The wiring electrically connects unit pixels, elements in the peripheral circuitry, and the electrodes 20a. The insulating film 13 includes an interlayer insulating film 13a and a passivation film 13b disposed on a top surface of the interlayer insulating film 13a. Each of the interlayer insulating film 13a and the passivation film 13b includes one or more stacked films.

The electrodes 20a serves as electrical connections to through electrodes 6 described later. The insulating film 13 has openings such that at least part of a top surface of each of the electrodes 20a is exposed in a top surface of the insulating film 13, and thus allowing the electrodes 20a to be used as test electrodes in semiconductor processing. Alternatively, the top surfaces of the electrodes 20a may be fully or partially covered with the insulating film 13, such that, for example, the electrodes 20a are reinforced against being damaged in processes of forming the through electrodes 6 described later. At this time, it is preferable that test electrodes connected to the wiring (not shown) and the electrodes 20a be provided in a region outside connections between the through electrodes 6 and the electrodes 20a. Such test terminals need not be provided on the top surface of the semiconductor substrate 1 covered with the light-transmissive plate 4. A test may be conducted using test terminals provided on the bottom surface or a lateral surface, or using external terminals instead of such test terminals provided in a region outside the connections.

In addition, on the top surface of the insulating film 13 (that is, above the one surface of the semiconductor substrate 1), optical components such as a microlens 3a and a color filter (not shown) are disposed above the light-receiving unit 2a correspondingly to the light-receiving region of each of the light-receiving elements. The optical components are provided above a region of the one surface of the semiconductor substrate. Above the region, the pillars 5b are not provided. In addition, on the optical components, a planarizing film 18 is provided between the pillars 5b and the semiconductor substrate 1 so as to cover top surfaces of the microlenses 3a. The microlenses 3a, the color filters, and the planarizing film 18 may not be provided if not necessary.

In addition, as shown in FIG. 3, the through electrodes 6 are provided in the peripheral part of the semiconductor substrate 1 so as to penetrate the semiconductor substrate 1 from the top surface to the bottom surface thereof. Each of the through electrodes 6 are composed of a through hole 7, an insulating film 8a, a conducting film 9a, and a conductor 10a. The through hole 7 penetrates the semiconductor substrate 1 in the thickness direction from the top surface to the bottom surface of the semiconductor substrate 1. The insulating film 8a is annularly provided in contact with the inside wall of the through hole 7. The conducting film 9a includes one or more stacked films and provided in contact with the inside wall of the insulating film 8a and a bottom surface of the electrode 20a. The conductor 10a is provided in contact with the inside wall of the conducting film 9a. The through electrodes 6 penetrates the semiconductor substrate 1 to electrically connect the electrodes 20a provided above the one surface of the semiconductor substrate 1 and electrically connected to the light-receiving elements, and respective external terminals 12 provided on the other surface of the semiconductor substrate 1.

In addition, rewiring 11 electrically connected to the through electrodes 6 is provided on the bottom surface of the semiconductor substrate 1. The rewiring 11 includes an insulating film 8b, a conducting film 9b, and a conductor 10b. The insulating film 8b is in contact with the bottom surface of the semiconductor substrate 1 and connected to a peripheral end of a bottom surface part of the insulating film 8a of the through electrode 6. The conducting film 9b is in contact with a bottom surface of the insulating film 8b and connected to a peripheral end of a bottom surface part of the conducting film 9a of the through electrode 6. The conductor 10b is in contact with a bottom surface of the conducting film 9b and connected to a bottom surface part of the conductor 10a. In addition, conductors 10c are formed below the bottom surface of the semiconductor substrate 1. The conductors 10c are connected to the conductor 10b of the rewiring 11 and partially exposed in the surface to function as an external electrode.

It is to be noted that the insulating film 8b is formed at least between the bottom surface of the semiconductor substrate 1 and a top surface of the conducting film 9b. It is also to be noted that the conductors 10c may be located right below the respective through electrodes 6. It is also to be noted that the structure to provide electrical connections between the electrodes 20a and the conductors 10c is not limited to the structure illustrated in FIG. 1 to FIG. 3 (the structure of the electrodes 20a, the through electrodes 6, and the rewiring 11 illustrated in FIG. 1 to FIG. 3). The electrical connections may be provided with a variety of structures.

In addition, in order to secure reliable external connections, external terminals 12 are provided on a bottom surface side of the semiconductor substrate 1 so as to be in contact with the conductors 10c. The external terminals 12 are electrically connected to connection terminals (not shown) of external wiring parts (not shown). Alternatively, the conductors 10c and the connection terminals may be directly connected.

In addition, an insulating film (overcoat) 15 having openings below the respective conductors 10c is provided on the bottom surface side of the semiconductor substrate 1 so as to cover the bottom surface side of the semiconductor substrate 1. The insulating film 15, which is provided in order to electrically insulate the conductors 10a and 10b from the ambient and protect them, is configured so as to cover at least the bottom surfaces of the conductors 10a and 10b but not the conductors 10c. Such electrical insulation may be secured not with the insulating film 15 but with a clearance (space) from a body on which the solid-state imaging device is mounted with the external terminals 12, on the bottom surface side of the semiconductor substrate 1.

The structure to provide electrical connections between the conductor 10c and the connection terminals and the structure to provide the electrical insulation are not limited to the structure illustrated in FIG. 1 to FIG. 3 (the structure of the external terminals 12 and the insulating film 15). The electrical connections and insulation may be provided with a variety of structures.

As described above, in the solid-state imaging device according to Embodiment 1, the through electrodes 6 establish electrical connections between the conductors 10c or the external terminals 12, which are formed below the bottom surface of the semiconductor substrate 1, and the peripheral circuitry and the elements of the unit pixels formed at the top surface of the semiconductor substrate 1. Providing the external terminals 12 on the bottom surface side of the semiconductor substrate 1, that is, on the side opposite to the top surface thereof covered with the light-transmissive plate 4, allows the surrounding region of the light-receiving unit 2a of the semiconductor substrate 1 to be made narrower, thus contributing to miniaturization of the semiconductor substrate 1.

It is to be noted that the structure to provide electrical connections between the elements provided on the top surface side of the semiconductor substrate 1 covered with the light-transmissive plate 4 and the external terminals provided on the bottom surface side is not limited to the above-described structure. The electrical connections may be provided by a variety of structures.

The following describes a configuration of the light-receiving unit 2a of the solid-state imaging device according to Embodiment 1.

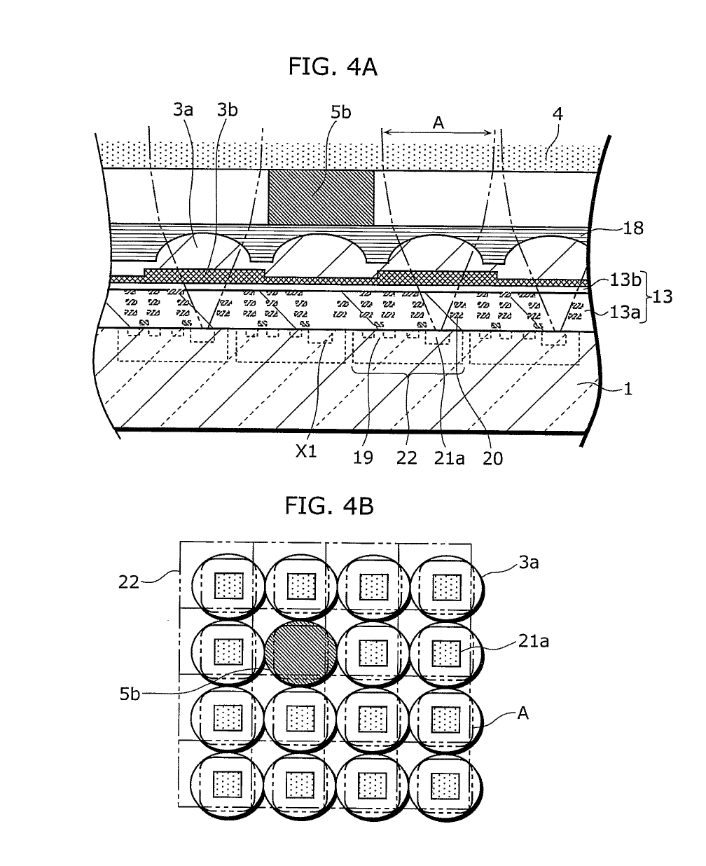

FIG. 4A is a sectional view of the light-receiving unit 2a of the solid-state imaging device according to Embodiment 1, and FIG. 4B is a schematic plan view of the light-receiving unit 2a viewed from the top of the solid-state imaging device.

As shown in FIG. 4A and FIG. 4B, in the solid-state imaging device according to Embodiment 1, the light-receiving unit 2a includes unit pixels 22 in a two-dimensional array. Each of the unit pixels 22 includes a light-receiving element 21a such as a photodiode. Each of the unit pixels 22 includes the light-receiving element 21a formed in the top surface of the semiconductor substrate 1, active elements 19, such as a transistor, provided in the vicinity of the light-receiving element 21a in order to control signals output from the light-receiving element 21a, and wiring 20. The active elements 19 includes, for example, controlling elements (for example, transfer transistors, amplifier transistors, address transistors, and reset transistors) for processing electric signals generated through photoelectric conversion by the light-receiving element 21a and transfer the electric signals to the outside of the unit pixel 22. The light-receiving element 21a and the active elements 19 are electrically connected to elements and electrodes in and outside the unit pixels 22 through the wiring 20 which includes one or more conductors and formed in and between the films included in the insulating film 13. The wiring 20 is not formed in regions of the insulating film 13, which is above the light-receiving elements 21a, corresponding to light-receiving regions A in order to avoid blocking incoming light toward the light-receiving elements 21a.

As described above, the color filters 3b and the microlenses 3a are provided on regions of the passivation film 13b corresponding to the light-receiving regions A of the light-receiving elements 21a, and the top surfaces of the microlenses 3a are covered with the planarizing film 18. The light-transmissive plate 4 is provided above the planarizing film 18 with a predetermined clearance.

The peripheral circuitry formed in the peripheral part of the semiconductor substrate 1 includes, for example, horizontal (H) and vertical (V) selecting circuits, a signal processing circuit, a signal holding circuit, a gain amplifier circuit, an A/D conversion circuit, an amplifier circuit, and a timing generator (TG). The peripheral circuitry may include a circuit for use other than controlling electric signals from the light-receiving unit 2a, such as a digital signal processor (DSP, a processor circuit for image data processing).

It is to be noted that the structures of the light-receiving unit 2a and the peripheral circuitry is not limited to the above described structure and may have a wide variety of structures. For example, a photo-shield film may be provided in a surrounding region of the light-receiving unit 2a and regions in the light-receiving unit 2a and outside the effective optical regions A of the light-receiving elements 21a.

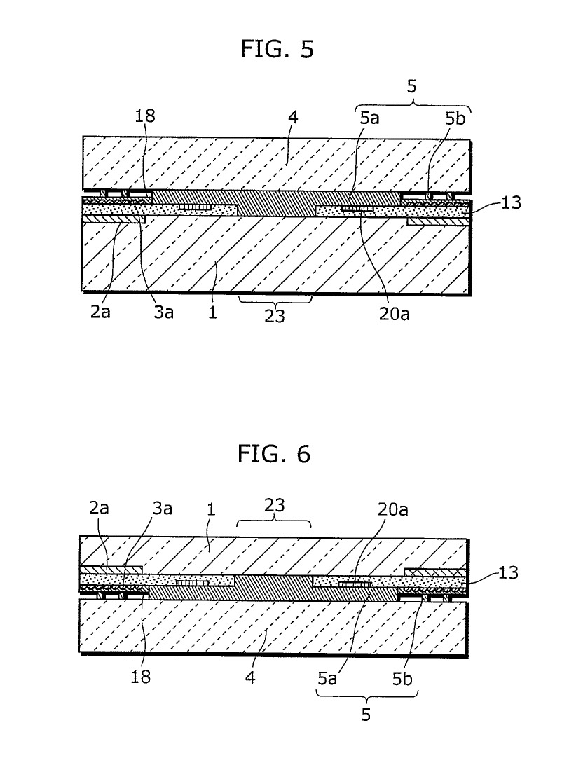

The following describes a method of manufacturing the solid-state imaging device according to Embodiment 1. FIG. 5 to FIG. 14 are sectional views illustrating steps of the method.

In the method shown in FIG. 5 to FIG. 14, a large semiconductor wafer having light-receiving units 2a with regular intervals on one surface thereof is diced into pieces (semiconductor substrates 1) each having a unit structure which includes one of the light-receiving units 2a. A large light-transmissive plate bonded to the one surface of the semiconductor wafer via the bonding layer 5 is also diced into pieces (light-transmissive plates 4) in a backend process. It is to be noted that the large semiconductor wafer is hereinafter referred to as a semiconductor substrate 1 in the same manner as the pieces of the large semiconductor wafer, and the large light-transmissive plate is hereinafter referred to as a light-transmissive plate 4 in the same manner as the pieces of the large light-transmissive plate in order to avoid confusion in the description.

FIG. 5 to FIG. 14 are sectional views schematically illustrating a structure between centers of unit structures of the solid-state imaging device arranged on both sides of a portion to be cut (a portion where the semiconductor wafer is separated), that is, a scribe region 23.

It is also to be noted that, in steps in shown in FIG. 6 to FIG. 13, the semiconductor substrate 1 is shown upside down compared to FIG. 1 to FIG. 4B, but the vertical directions of top and bottom in FIG. 6 to FIG. 13 are described according to the drawings.

First, light-receiving elements, that is, light-receiving units 2a are formed on the semiconductor substrate 1 in a manner such that a pair of the light-receiving units 2a are arranged on both sides of a scribe region of the semiconductor substrate 1.

Next, as shown in FIG. 5, a light-transmissive plate 4 is bonded, via a bonding layer 5 patterned into a desired shape, to a top surface of the semiconductor substrate 1 in or above which the light-receiving units 2a, microlenses 3a, electrodes 20a, and an insulating film 13 are formed. Here, the desired shape includes two patterns: a first pattern provided in a region surrounding the light-receiving unit 2a which is an element region of the semiconductor substrate 1 and a region in which light-receiving elements are formed; and a second pattern provided above the element region and apart from the first pattern. In the bonding layer 5, desired unit structures are formed with regular intervals in positions corresponding to the light-receiving unit 2a. Each of the unit structures includes a circumferential layer 5a provided so as to surround the light-receiving unit 2a of the semiconductor substrate 1 and pillars 5b provided above the light-receiving unit 2a and apart from the circumferential layer 5a. In addition, the semiconductor substrate 1 and the light-transmissive plate 4 are partially bonded to each other in a manner such that a clearance (space) is formed between the semiconductor substrate 1 and the light-transmissive plate 4 and above the light-receiving unit 2a of the semiconductor substrate 1.

Next, as shown in FIG. 6, a top surface (the bottom surface in FIG. 3) of the semiconductor substrate 1 is polished to thin the semiconductor substrate 1 to a predetermined thickness, using the light-transmissive plate 4 as a support.

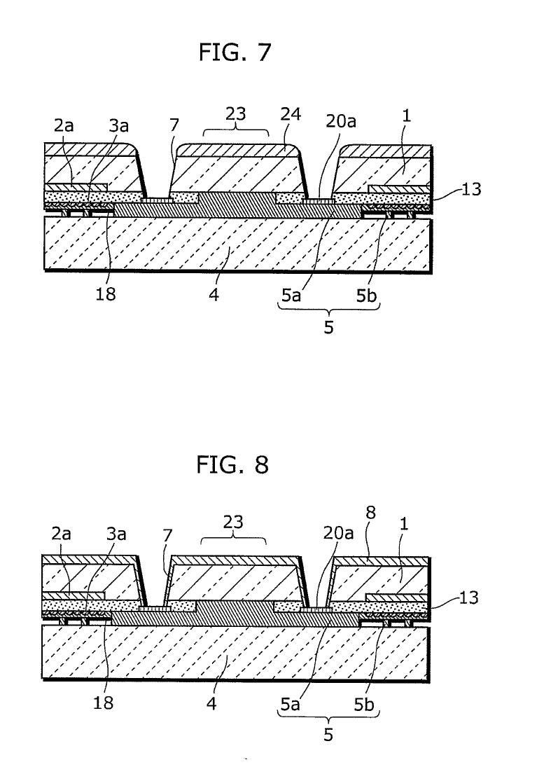

Next, as shown in FIG. 7, a mask layer 24 which has openings in positions above the electrodes 20a of the semiconductor substrate 1 is provided on the top surface side (the bottom surface side in FIG. 3) of the semiconductor substrate 1. The portions of the semiconductor substrate 1 exposed in the openings of the mask layer 24 and portions of the insulating film 13 therebelow are removed using a technique such as dry etching, so that through holes 7 are formed up to a top surface of the electrode 20a. In this step, the mask layer 24 remaining after the etching is removed by, for example, plasma ashing and a wet process before or after the insulating film 13 is penetrated. The through holes 7 may be formed by wet etching as well as dry etching, for which a preferable etching gas and an etching solution are selected, respectively.

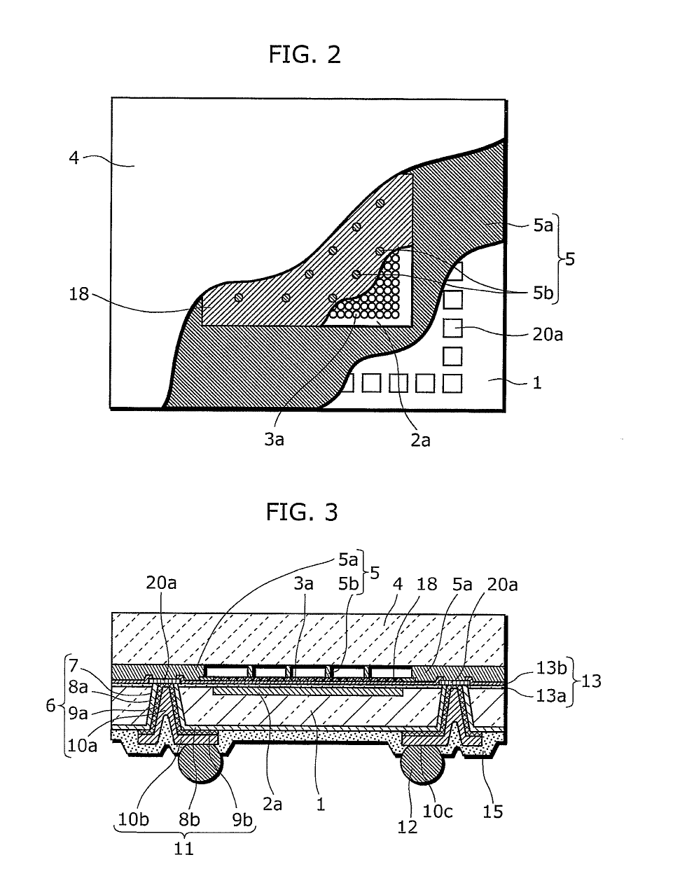

Next, as shown in FIG. 8, an insulating film 8 is formed on the inside wall of the through holes 7 and the top surface (the bottom surface in FIG. 2) of the semiconductor substrate 1 in a manner such that at least part of a top surface of each of the electrodes 20a is exposed. Here, the insulating film 8 is formed by, for example, first integrally forming a chemical vapor deposition (CVD) film of silicon oxide to cover all over the inside walls of the through holes 7 and the top surface of the semiconductor substrate 1, and then removing the insulating film 8 from the bottoms of the through holes 7 using a technique such as dry etching to expose the top surfaces of the electrodes 20a.

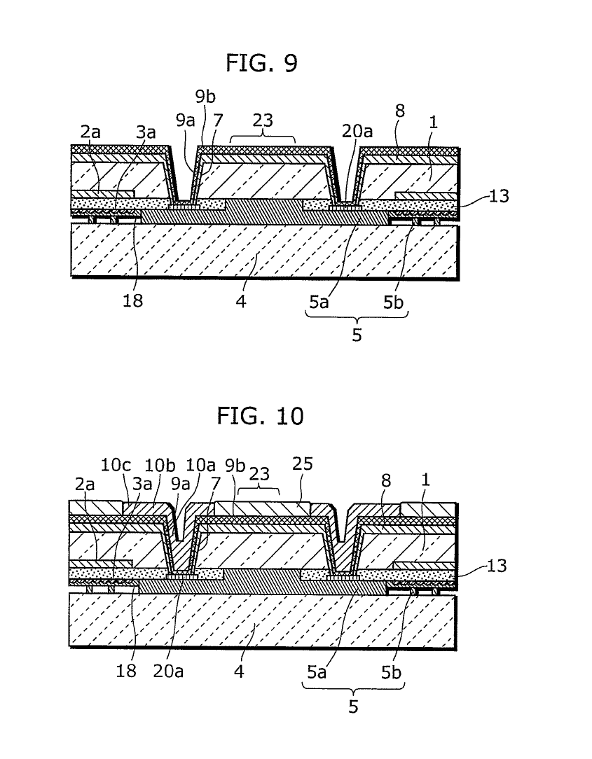

Next, as shown in FIG. 9, a conducting film 9a and a conducting film 9b are formed on the inside wall of the through holes 7, the insulating film 8 formed on the top surface (the bottom surface in FIG. 2) of the semiconductor substrate 1, and the exposed surfaces of the electrodes 20a at the bottoms of the through holes 7 using a technique such as spattering.

Next, as shown in FIG. 10, a mask layer 25, which has openings in the regions where through electrodes are to be formed (where through electrodes 6 of the semiconductor substrate 1 are to be formed) and where wiring having a desired shape is to be formed (where rewiring 11 of the semiconductor substrate 1 is to be formed) is formed on the conducting film 9b. Then, conductors 10a, 10b, and 10c are formed by plating using the mask layer 25. Here, in the case where, for example, stacked films of Ti/Cu are used as the conducting film 9a and 9b, it is preferable that the conductors 10a, 10b, and 10c include Cu. It is also preferable that a mask layer 25 cover at least the scribe region 23 and that the conductors 10a, 10b, and 10c be not formed in the scribe region 23 by the plating so that dicing described later is easily performed.

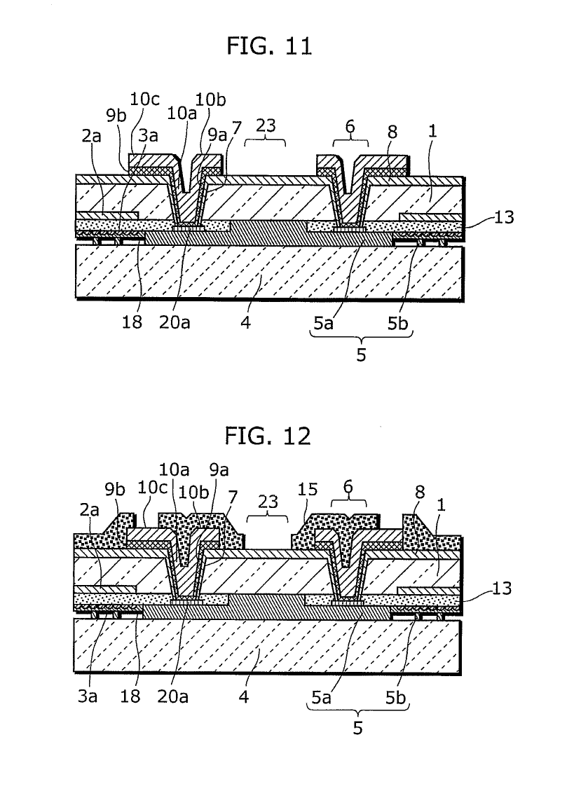

Next, as shown in FIG. 11, first the mask layer 25 is removed by a wet process, then, the conducting film 9b is removed using a technique such as wet-etching using the conductors 10a, 10b, and 10c as a mask so that the conducting film 9b remains in the regions where the conductors 10a, 10b, and 10c are present.

Although the insulating film 8 in the method shown in FIG. 5 to FIG. 14 covers all over the top surface of the semiconductor substrate 1, the insulating film 8 needs to be formed at least between the semiconductor substrate 1 and the conductors 10a, 10b, and 10c, and may be etched together with the conducting film 9b except in the regions where the conductors 10a, 10b, and 10c are present. In addition, the through electrode 6 and the rewiring 11 may be formed by first forming the conductors 10a, 10b, and 10c all over the top surfaces of the conducting films 9a and 9b, and then etching the conductors 10a, 10b, and 10c with a mask over the regions where the through electrodes and the wiring are to be formed.

Next, as shown in FIG. 12, an insulating film 15 is formed to provide electrical insulation to the conductors 10a, 10b, and 10c and the conducting films 9a and 9n on the top surface side (the bottom surface side in FIG. 2) of the semiconductor substrate 1 and protect the surfaces thereof. It is preferable that the insulating film 15 secure electrical insulation by covering at least the conductors 10a and 10b, but not the conductor 10c, and have openings at least above the scribe region 23 so that dicing is easily performed.

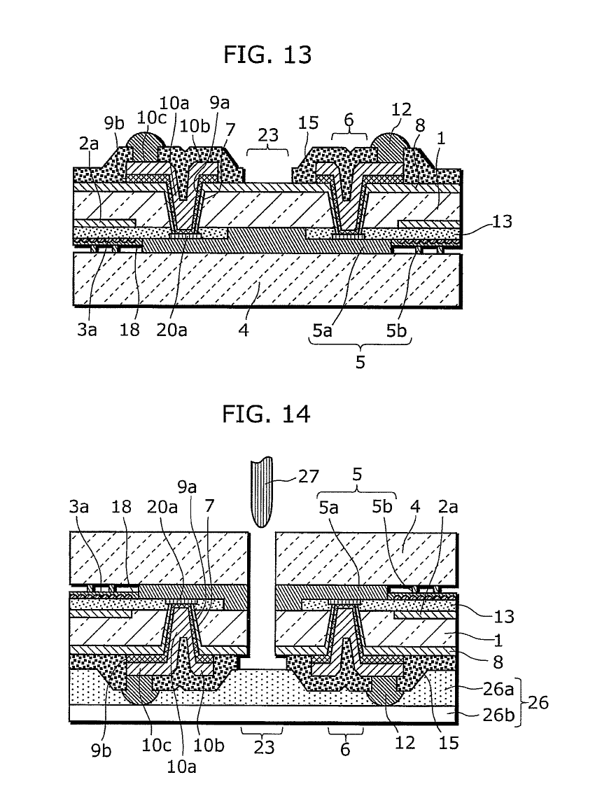

Next, as shown in FIG. 13, external terminals 12 are formed on the conductors 10c, so that the external terminals 12 connect the respective conductors 10c. The external terminals 12 are formed by, for example, placing a solder ball on each of the conductor 10c and attaching the solder ball to the conductor 10c by reflow processing. In consideration of adaptivity to a dicing process, the external terminals 12 may be formed after the dicing process described later.

Through the steps shown in FIG. 7 to FIG. 13, an electrical connection path is thus formed extending from the electrodes 20a, which are electrically connected to elements provided on the bottom surface side of the semiconductor substrate 1 to the external terminals 12 formed on the top surface side of the semiconductor substrate 1 via the through electrodes 6 in the through holes 7.

Next, as shown in FIG. 14, a bottom surface of the insulating film 15 is bonded to a dicing sheet 26 in a manner such that the external terminals 12 are embedded in an adhesive layer 26a on a top surface of a substrate 26b of the dicing sheet 26. Then, a semi-through groove is formed above a dicing line in the scribe region 23 by a dicing blade 27. The semiconductor substrate 1 is separated in the scribe region 23 by cutting and removing the stack including semiconductor substrate 1 in the scribe region 23 using the dicing blade 27 shaped to have a desired width, so that the semiconductor substrate 1 is diced into pieces each having a unit structure which includes the light-receiving unit 2a.

Here, as the insulating film 13 has an opening above the scribe region 23, possibility of damaging of the blade, such as chipping, during cutting in the scribe region 23 is reduced, and thus yields and reliability of the solid-state imaging devices is increased. Furthermore, in the case where the scribe region 23 is removed by etching, the etching process may be simplified, and thus the productivity may be increased.

The semiconductor substrate 1 and the light-transmissive plate 4 may be cut in two or more cutting in order to reduce possibility of damaging a composite structure due to integral separation of the composite structure of the semiconductor substrate 1 and the light-transmissive plate 4. Alternatively, the stack may be diced from the side of the semiconductor substrate 1 using the dicing sheet 26 as a support provided on the surface of the light-transmissive plate 4 in order to reduce the possibility of damaging the semiconductor substrate 1. The cutting method is not limited to blade dicing, and may be performed using a variety of techniques such as etching, laser dicing, and a combination thereof.

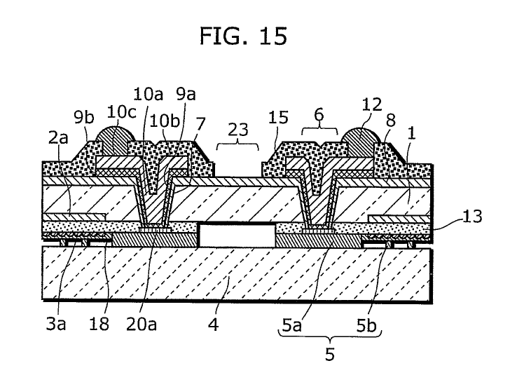

In addition, an opening may be formed in the bonding layer 5 and above the scribe region 23 as shown in FIG. 15 in a step preceding the dicing shown in FIG. 14. That is, the bonding layer may be formed above a region of the one surface of the semiconductor substrate 1. The region is a region other than the scribe region. Thereby, the circumferential layer 5a is separated between adjacent unit structures and a hollow structure is formed in the scribe region 23, so that structural differences between the region where the circumferential layer 5a is formed and the region where the pillars 5b are formed are minimized. This reduces possibility of warpage and dishing. In addition, this prevents damaging of the composite structure due to differences in physical properties between the bonding layer 5 and the semiconductor substrate 1, and between the bonding layer 5 and the light-transmissive plate 4. Moreover, in the case where the scribe region 23 is removed by etching, the etching process may be simplified.

In addition, although solid-state imaging devices are produced by dicing an intermediate product prepared by bonding the large semiconductor substrate 1 and the large light-transmissive plate 4 in the method shown in FIG. 5 to FIG. 14, they may be bonded after either or both of the semiconductor substrate 1 and the light-transmissive plate 4 are diced.

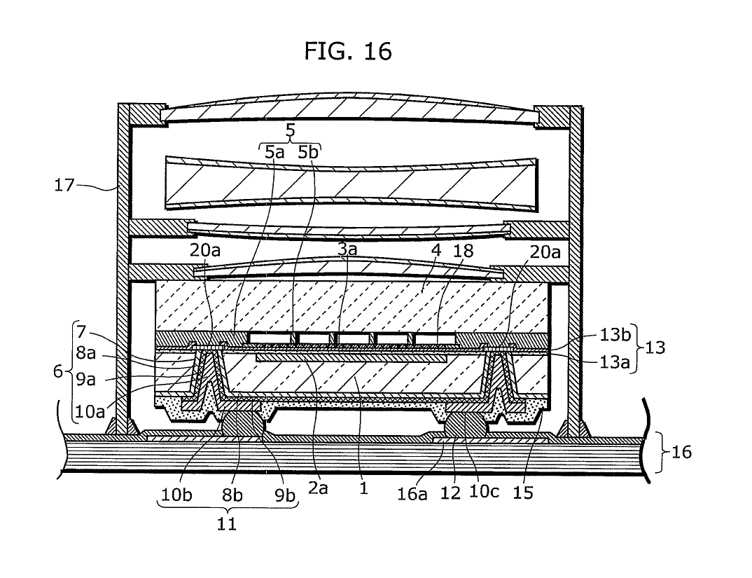

FIG. 16 is a sectional view illustrating a mounting configuration of the solid-state imaging device according to Embodiment 1 of the present invention.

The solid-state imaging device according to Embodiment 1 is mounted so as to electrically connect mounting terminals 16a formed in a wiring member 16 and the external terminals 12, and incorporated into an optical module which has a lens barrel 17 provided with an optical system including a lens, to be installed on a variety of electronic apparatuses.

The following describes examples of materials for the solid-state imaging device according to Embodiment 1.

A Si semiconductor substrate is used as the semiconductor substrate 1. The elements including the light-receiving elements 21a and the wiring 20 are formed using ordinary semiconductor processing. For example, a gate oxide film is a SiO₂ film, a gate electrode is made of polysilicon, and a contact electrode is made of W (tungsten). The wiring 20 made of a conductive material mainly including Al and Cu is formed in the interlayer insulating film 13a in which one or more films, such as a silicon oxide film, a tetraethoxysilane (TEOS) film, and a fluorinated silicon oxide (FSG) film, are stacked. The wiring 20 is electrically connected to the elements. The passivation film 13b is made by stacking one or more films such as a silicon nitride film. The photo-shield film 14 is generally formed as an opaque member such as a metal film formed between the films in the insulating film 13, and the metal film is mainly made of a elements such as W, Ti, Cu, and Al.

The microlenses 3a are formed by patterning and reflowing, for example, a boron phosphor silicate glass film (BPSG film) to provide it with a desired shape. The color filters 3b are formed by, for example, pattering precolored resins. The planarizing film 18 is formed by coating with a fluid transparent material such as BPSG film, a spin-on-glass (SOG) film, and acrylic transparent resin, and planarization using a flow method.

The light-transmissive plate 4 is a transparent resin plate such as a silicate glass plate and an acrylic plate having a thickness of 0.1 to 1.0 mm. The light-transmissive plate 4 may be provided with an optical filter such as an anti-reflection film or a wavelength filer on one or each of its top surface and bottom surfaces. The optical filter is formed by stacking one or more inorganic films such as a siliceous film.

The bonding layer 5 is an acrylic transparent resin film and a siliceous glass layer having an adjusted refractive index.

The rewiring 11 is made by forming wiring in a stress relieving layer in which one or more layers such as a polyimide resin film and an epoxy resin film are stacked. The wiring is made of a conductive material which mainly includes, for example, Cu and Al. The external terminals 12 are solder bumps which mainly include, for example, SnAg and SnAgCu.

The wiring member 16 is provided by forming lines made of a conductive material such as Cu in a resin film such as an epoxy resin substrate and a polyimide resin film which ensures flexibility. In this case, the wiring member 16 may further include a semiconductor substrate and a ceramic substrate in which wiring is formed, and an intermediate wiring member such as a resin substrate.

The basic structure of the solid-state imaging device according to Embodiment 1, the method of manufacturing the same, and materials for the same have been thus described. The following describes features of the solid-state imaging device according to Embodiment 1.

As shown in FIG. 1 to FIG. 3, the bonding layer 5 which bonds the semiconductor substrate 1 and the light-transmissive plate 4 of the solid-state imaging device according to Embodiment 1 includes the circumferential layer 5a formed above a peripheral region surrounding the light-receiving unit 2a of the semiconductor substrate 1 and the pillars 5b formed above the light-receiving unit 2a with desired intervals therebetween. In this configuration, compared to a solid-state imaging device in which the semiconductor substrate 1 and the light-transmissive plate 4 are bonded only by the circumferential layer 5a, the peripheral region of the semiconductor substrate 1 necessary for securing a comparable bonding region is smaller in area by the area of pillars 5b. That is, providing the pillars 5b allows miniaturization of a solid-state imaging device without reducing bonding strength. The structure of the solid-state imaging device according to Embodiment 1 is therefore applicable not only to a solid-state imaging device having a structure including the through electrodes 6 as described above but also to a small-size solid-state imaging device, such as a back-side illumination solid-state imaging device, which has a peripheral region surrounding a light-receiving unit and reduced in area with external terminals formed on a surface opposite to a surface of the semiconductor substrate in which the light-receiving unit is formed.

In addition, compared to a solid-state imaging device in which the semiconductor substrate 1 and the light-transmissive plate 4 are bonded only by the circumferential layer 5a and which has a comparable size, the solid-state imaging device according to Embodiment 1 has a bonding region between the semiconductor substrate 1 and the light-transmissive plate 4 increased by the area of the pillars 5b. That is, in the case where the solid-state imaging devices are comparable in overall dimensions, the solid-state imaging device provided with the pillars 5b has higher bonding strength. The structure of the solid-state imaging device according to the present invention therefore allows manufacturing optical devices which is more resistant to impact, easier to handle, and highly reliable, providing higher productivity.

In addition, compared to a solid-state imaging device in which the semiconductor substrate 1 and the light-transmissive plate 4 are bonded only by the circumferential layer 5a, the pillars 5b in the solid-state imaging device according to Embodiment 1 reduce influence of the hollow region in the bonding layer 5. That is, providing the pillars 5b minimizes structural differences between the region where the light-receiving unit 2a is formed and the surrounding region thereof in the solid-state imaging device. As a result, possibility of warpage due to the hollow region is reduced, and thus preferable device characteristics are provided. In particular, since a hollow region greatly affects the solid-state imaging device having a thin-thickness structure, a structure including such pillars is suitable for thin-thickness solid-state imaging devices. For example, a structure including such pillars is suitable for optical devices including an ultra-thin (approximately 5 to 15 micrometers) semiconductor substrate, such as a back-side illumination optical device.

In addition, providing the pillars 5b minimizes differences in polishing pressure at which the top surface of the semiconductor substrate 1 is polished in the thinning step shown in FIG. 6, and thus possibility of dishing is reduced in the solid-state imaging device according to Embodiment 1. Thus, the structure of the solid-state imaging device according to Embodiment 1 is appropriate for a manufacturing method in which a large semiconductor substrate is thinned after being bonded to a large light-transmissive plate, and thus optical devices are manufactured with high productivity.

In addition, in the solid-state imaging device according to Embodiment 1, the bonding layer 5 is not formed in the light-receiving region A, which corresponds to each of the light-receiving elements 21a in the light-receiving unit 2a, except in the regions where the pillars 5b are formed above the light-receiving unit 2a. That is, the bonding layer 5 formed into a desired shape is hollow in the light-receiving regions A corresponding to the respective light-receiving elements, so that the optical characteristics of the solid-state imaging device are not affected by the bonding layer 5. Thus, even when a void occurs in forming of a film, the void no longer affects the optical characteristics when the bonding layer 5 is patterned to have an opening in each of the light-receiving regions A. Thus, the structure of the solid-state imaging device according to Embodiment 1 is appropriate for a manufacturing method in which a large semiconductor substrate and a large light-transmissive plate are bonded to each other to provide an intermediate product which is relatively likely to include a void, and thus solid-state imaging devices are manufactured with high productivity.

In addition, in the solid-state imaging device according to Embodiment 1, the bonding layer 5 is not formed in the light-receiving region A, which corresponds to each of the light-receiving elements 21a in the light-receiving unit 2a, except in the regions where the pillars 5b are formed above the light-receiving unit 2a. It is therefore unnecessary to take into consideration the influence of physical characteristics of the bonding layer 5 on the optical characteristics of the solid-state imaging device, so that the flexibility in the choice of a material for the bonding layer 5 is high. Thus, an optimum material for the bonding layer 5 may be chosen without considering the optical characteristics thereof even in the case where backend processes such as a thinning process and a wet process are performed after an intermediate product is provided by bonding a large semiconductor substrate and a large light-transmissive plate. The solid-state imaging device according to Embodiment 1 is therefore technically easy to manufacture, and thus providing cost advantages.

In addition, in the solid-state imaging device according to Embodiment 1, the positions of the pillars 5b partially overlap with part of the light-receiving regions A corresponding to the respective light-receiving elements 21a in the light-receiving unit 2a. That is, as shown in FIG. 4A, one of the pillars 5b is disposed above one of the light-receiving regions A corresponding to the respective light-receiving elements 21a indicated by X1 in the light-receiving unit 2a, so that the pillar 5b makes the optical characteristics of one of the unit pixels 22 indicated by X1 ineffective. It is therefore preferable to use, as an alternative to a pixel signal from the unit pixel 22 indicated by X1 with the pillar 5b disposed thereabove, a signal obtained through an analysis of a pixel signal from another unit pixel 22 in the vicinity of the unit pixel 22 in order to compensate the loss in the pixel signal due to the pillar 5b. It is also preferable to dispose, as the light-receiving element 21a indicated by X1 with the pillar 5b disposed thereabove, a dummy element which outputs no pixel signal.

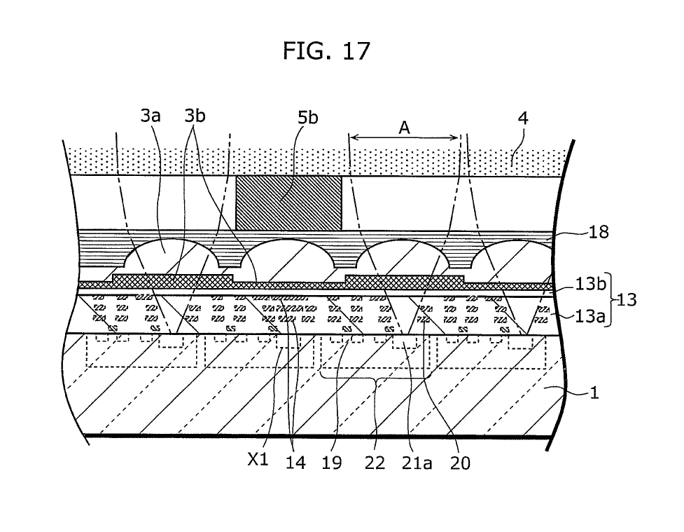

Alternatively, in the solid-state imaging device according to Embodiment 1, as shown in FIG. 17, the photo-shielding film 14 may be provided in the insulating film 13 so as to cover the light-receiving region A corresponding to the light-receiving element 21a indicated by X1 with the pillar 5b disposed thereabove. In this case, a pixel signal output from the light-receiving element 21a indicated by X1 with the pillar 5b disposed thereabove may be used for black level (noise) detection. Generally, a unit pixel 22 for black level detection is formed in a surrounding region of the light-receiving unit 2a. However, when a unit pixel 22 for black level detection is formed in the light-receiving unit 2a, accuracy in black level correction is increased by using, for signal correction, a signal output from another unit pixel 22 in the vicinity of the unit pixel 22 for black level detection. In this configuration, the regions where the pillars 5b are disposed are effectively used.

Here, the photo-shield film 14 may be formed in the same manner as the wiring 20 formed in the interlayer insulating film 13a as shown in FIG. 17. Alternatively, light may be blocked not by the photo-shield film 14 by the pillars 5b or the color filters 3b below the pillars 5b made of a light blocking material. That is, the pillar 5b may have a structure for blocking light in the light-receiving region of the light-receiving element 21a. Alternatively, the unit pixel 22 needs not be provided below the pillar 5b. Furthermore, a functional element and an alignment mark for process control may be provided below the pillar 5b instead of the unit pixel 22. In this configuration, the regions where the pillars 5b are disposed are effectively used.

In addition, it is preferable that the shape, size, and positions of the pillars 5b in the solid-state imaging device according to Embodiment 1 be optimized in consideration of an possible aspect ratio of each of the pillars 5b, and the size and pitch of the light-receiving region A of the light-receiving elements 21a.

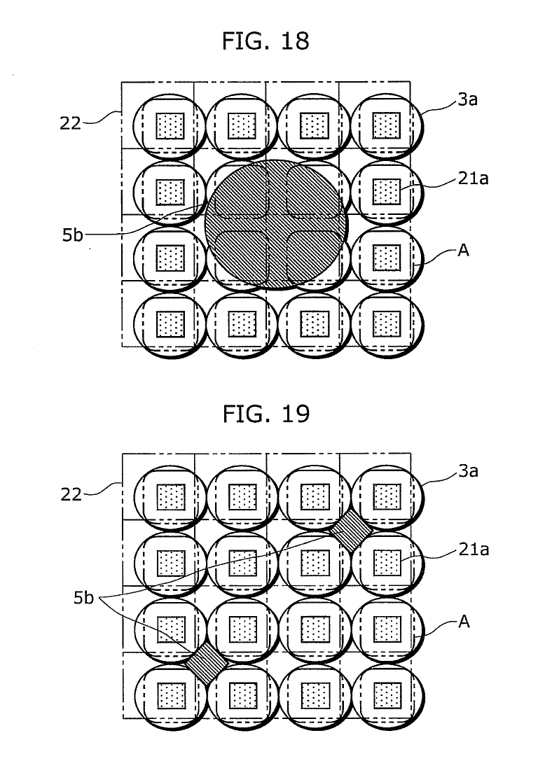

For example, each of the pillars 5b may be formed to overlap a plurality of the unit pixels 22 as schematically shown in FIG. 18, or may be formed not to overlap the light-receiving regions A corresponding to the respective unit pixels 22 as schematically shown in FIG. 19. That is, each of the pillars 5b may be disposed to overlap with the light-receiving regions A or may be disposed not to overlap the light-receiving regions A.

In addition, although each of the pillars 5b in the solid-state imaging device according to Embodiment 1 have been described as a stand-alone cylinder because the light-receiving elements 21a are arranged so tightly that the spacing between the light-receiving regions A is small, the pillars 5b may be a columnar pillar having any desired sectional shape. Furthermore, each of the pillars 5b needs not stand alone and may be formed to be coupled with each other or with the circumferential layer 5a. In this configuration, deformation of the pillars 5 may be prevented. Therefore, such a coupling structure is suitable for an apparatus having a relatively large spacing between the light-receiving regions A, such as a light-receiving and -emitting device.

In addition, it is preferable that an alignment pattern for alignment of the semiconductor substrate 1 and the light-transmissive plate 4 be formed on the bonding layer 5 in the solid-state imaging device according to Embodiment 1 in order to increase accuracy positioning of patterns.

In addition, the planarizing film 18 is formed above the light-receiving unit 2a in the solid-state imaging device according to Embodiment 1 as shown in FIG. 4A and FIG. 4B. The planarizing film 18 eliminates influence of the uneven shape of the microlenses 3a and the color filters 3b, thus increasing accuracy in pattering of the bonding layer 5 for better bondability of the pillar 5b. Here, it is preferable that the planarizing film 18 be formed not only above the region where the light-receiving unit 2a of the semiconductor substrate 1 is formed but also above the surrounding region of the light-receiving unit 2a so that there is no difference in height between the pillars 5b and the circumferential layer 5a.

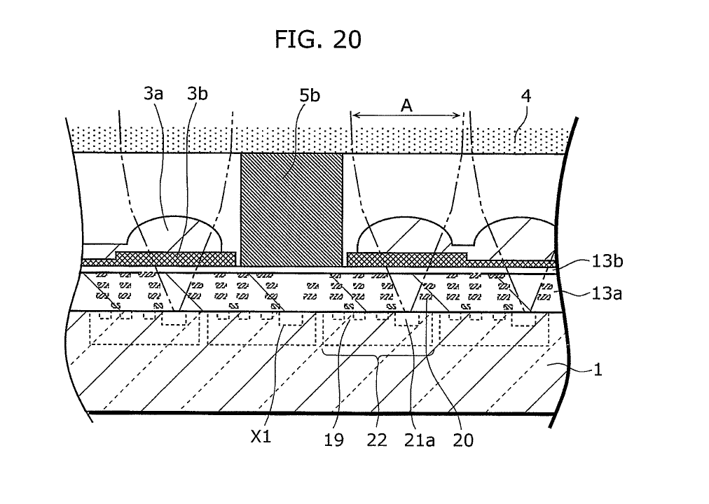

In addition, in the solid-state imaging device according to Embodiment 1, the optical components 3 such as the microlenses 3a and the color filters 3b may not be formed above the light-receiving element 21a indicated by X1 with the pillar 5b formed thereabove, and the pillars 5b may be bonded to the insulating film 13 as shown in FIG. 20. In this configuration, the influence of the uneven shape of the surface is reduced without the planarizing film 18, thus bondability of the pillars 5b are increased.

In the solid-state imaging device according to Embodiment 1, the circumferential layer 5a formed in the surrounding region of the light-receiving unit 2a of the semiconductor substrate 1 may be provided with a slit having a desired shape. This configuration is appropriate for a solid-state imaging device having such a relatively large peripheral region that the bonding strength is sufficient. When the circumferential layer 5a has a slit, the surrounding region may have a hollow structure in the same manner as the region where the light-receiving unit 2a of the solid-state imaging device is formed. This minimizes differences in the structure of the bonding layer 5 between the region where the light-receiving unit 2a is formed and the surrounding region of the solid-state imaging device, and thus the influence of the differences, such as warpage, is reduced. In addition, the slit may relax stress, so that the influence of differences in physical properties between the bonding layer 5 and the semiconductor substrate 1 and between the bonding layer 5 and the light-transmissive plate 4, such as an interfacial failure, may be reduced. In the configuration in which a slit is provided in the surrounding area, the solid-state imaging device has improved characteristics and reliability.

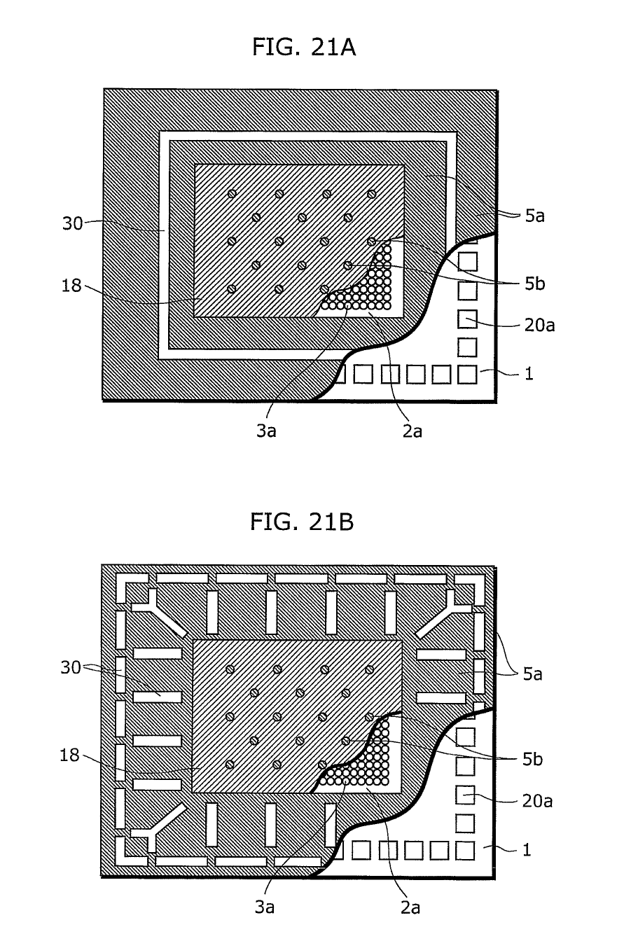

FIG. 21A and FIG. 21B are plain views of the solid-state imaging device illustrating the configuration. FIG. 21A and FIG. 21B each schematically show a shape of the circumferential layer 5a as a plan viewed from the top of the solid-state imaging device, and the light-transmissive plate 4 is omitted from the drawings for simplification. In FIG. 21A, the circumferential layer 5a is split into pieces by one or more slits 30. In FIG. 21B, the circumferential layer 5a is split into sections by one or more slits 30 and the sections are connected to each other by narrow parts.

The following describes an exemplary configuration of the bonding layer 5 of the solid-state imaging device according to Embodiment 1.

For example, it is preferable that the bonding layer 5 be made of a material which is cost effective and easy to handle, such as acrylic or epoxy adhesive resin film. In the bonding method, a bonding material (the material for the bonding layer 5) is applied to the semiconductor substrate 1 and patterned into a desired shape to form the bonding layer 5, and then the bonding layer 5 and the light-transmissive plate 4 are bonded using a technique such as thermo compressing bonding and UV bonding. The bonding layer 5 preferably has a thickness which provides satisfactory strength and patternability, for example, on the order of several micrometers to several hundred micrometers.

Alternatively, it is also preferable that the bonding layer 5 be made of, for example, fluid acrylic adhesive resin. In the bonding method using the bonding layer 5, a bonding material is applied to the semiconductor substrate 1 and patterned into a desired shape to form the bonding layer 5, and then the bonding layer 5 and the light-transmissive plate 4 are bonded using a technique such as thermo compressing bonding and UV bonding. The bonding layer 5 preferably has a thickness which provides satisfactory application properties and patternability, for example, on the order of several micrometers to several hundred micrometers. In comparison with resin films, the adhesive resin advantageously allows flexible setting of the thickness of the bonding layer 5, fits well to level differences in the surface to which the adhesive resin is applied (for example, level differences in the peripheral region of the solid-state imaging device and level differences due to microlenses 3a), and allows easy planarization of a top surface of the bonding layer 5.

The method in which such adhesive resin is used has also been general in conventional techniques and allows forming of the bonding layer 5 and bonding by the bonding layer 5 even at relatively low temperatures. However, in the case where the method in which such adhesive resin is used, it is necessary to take into consideration the patternability of the pillars 5b. The bonding layer 5 preferably has a thickness which allows the pillars 5b to have a pattern of an aspect ratio up to approximately two. Accordingly, for example, in the case where the light-receiving elements 21a are arranged at a narrow pitch as in the solid-state imaging device according to Embodiment 1, it is preferable that the pillars 5b be formed to cover one or more unit pixels 22 so that sufficient patternability is achieved. On the other hand, in the case of a device having a relatively large space between the light-receiving regions A, such as a light-receiving and -emitting device, the pillars 5b may be formed using a conventional method so that the pillars 5b do not overlap the light-receiving region A.

The flexibility in the choice of a material for the bonding layer 5 is high. For example, inorganic materials such as a silicate glass layer, a Si substrate, or a metal film may be a material for the bonding layer 5 as an alternative to the above-mentioned resin film and adhesive resin. Since such alternative materials hardly deteriorate due to light in comparison with adhesive resin, an optical device with the bonding layer 5 including an inorganic material, a Si substrate, and a metal film is usable for light of a wide range of wavelengths. Therefore, a configuration in which the bonding layer 5 includes an inorganic material, a Si substrate, and a metal film is appropriate for, for example, a light-receiving device for a short wavelength to be used in a Blu-ray recorder. Alternatively, since the light-receiving region A of the desired light-receiving element 21a has a hollow, the bonding layer 5 may be made of an opaque material to block light.

In addition, it is preferable that the light-transmissive plate 4 has a bonding part to the bonding layer 5 and the bonding layer 5 has a bonding part to the light-transmissive plate 4 and materials for the respective bonding parts have similar physical properties so that light-transmissive plate 4 and the bonding layer 5 are chemically bonded to each other, or the semiconductor substrate 1 has a bonding part to the bonding layer and the bonding layer 5 has a bonding part to the semiconductor substrate 1 and materials for the respective bonding parts have similar physical properties so that semiconductor substrate 1 and the bonding layer 5 are chemically bonded to each other. For example, the bonding parts are preferably made of a silicate glass material or an organic material.

Bonding using the bonding layer 5 may be implemented by applying a liquid silicate glass material such as boron phosphor silicate glass (BPSG), nondoped silicate glass (NSG), or spin-on glass (SOG) to the surface of the semiconductor substrate 1 to form a silicate glass layer, patterning the silicate glass layer into a desired shape to form the bonding layer 5, and then bonding the bonding layer 5 to the light-transmissive plate 4. Alternatively, bonding using the bonding layer 5 may be implemented by forming a silicate glass layer using a technique such as vapor deposition, patterning the silicate glass layer into a desired shape to form the bonding layer 5, and then bonding the bonding layer 5 to the light-transmissive plate 4. Such configurations in which a silicate glass layer is used for bonding provides the bonding layer 5 with fine patternability, and is thus appropriate for an optical device in which the light-receiving elements 21a are arranged at narrow pitches. In addition, an optical device in which a silicate glass layer is used for bonding is more resistant to deformation compared to an optical device in which an adhesive resin is used for bonding. In the case where the light-transmissive plate 4 or a surface film (for example, an optical filter film) on the light-transmissive plate 4 is made of siliceous glass, it is preferable that the semiconductor substrate 1 and the light-transmissive plate 4 be directly bonded using a technique such as thermo compressing bonding. Such a configuration is appropriate for providing the bonding layer 5 with a fine pattern. In this case, the semiconductor substrate 1 and the light-transmissive plate 4 are directly bonded at a relatively low temperature by activating the surfaces thereof through chemical treatment using an alkali and a hydrofluoric acid and precision polishing. On the other hand, in the case where the bonding layer 5 is formed by forming a silicate glass layer on the light-transmissive plate 4 and patterning the silicate glass layer into a desired shape, it is preferable that surface films (the insulating film 13 and the planarizing film 18) of the semiconductor substrate 1 be made of silicate glass layers and that the semiconductor substrate 1 and the light-transmissive plate 4 be directly bonded using a technique such as thermo compressing bonding. When the light-transmissive plate 4 and the semiconductor substrate 1 are directly bonded with the interface made of silicate glass materials, the light-transmissive plate 4 and the semiconductor substrate 1 are chemically bonded (silane coupling), and thus an optical device having high bonding strength in the interfaces is provided. Alternatively, the bonding layer 5 may be bonded to the light-transmissive plate 4 and the semiconductor substrate 1 via an appropriate adhesive agent.

Alternatively, a semiconductor substrate such as a Si substrate may be used as the bonding layer 5. In this case, bonding using the bonding layer 5 may be implemented by, for example, bonding a Si substrate and the light-transmissive plate 4, polishing the Si substrate to a desired thickness, patterning the Si substrate into a desired shape to form the bonding layer 5, and then bonding the bonding layer 5 to the semiconductor substrate 1. Such a configuration where a Si substrate is used as the bonding layer 5 provides the bonding layer 5 with fine patternability, and is therefore appropriate for an optical device in which the light-receiving elements 21a are arranged at narrow pitches. In addition, since the Si substrate transmits little light, the bonding layer 5 made of the Si substrate may be also used for blocking light. In addition, an optical device in a configuration in which a Si substrate is used as the bonding layer 5 is resistant to deformation compared to the bonding layer 5 of adhesive resin. In the case where the light-transmissive plate 4 of a surface film (for example, an optical filter film) on the light-transmissive plate 4 is made of siliceous glass, it is preferable that the semiconductor substrate 1 and the light-transmissive plate 4 be directly bonded via the bonding layer 5 using a technique such as anodic bonding. Such a configuration is appropriate for providing the bonding layer 5 with a fine pattern. In the case where the light-transmissive plate 4 is made of aluminosilicate glass, the light-transmissive plate 4 keeps matching with silicon monocrystal over a wide range of temperature while expanding due to heat, and thus an optical device with excellent heat resistance is provided. In the case where the Si substrate is used as the bonding layer 5, it is preferable that surface films (the insulating film 13 and the planarizing film 18) of the semiconductor substrate 1 be planarized for better adhesion to the bonding layer 5 and that the semiconductor substrate 1 be directly bonded, via a surface film made of siliceous glass thereon, to the bonding layer 5 using a technique such as anodic bonding. Alternatively, the bonding layer 5 may be bonded to the light-transmissive plate 4 and the semiconductor substrate 1 via an appropriate adhesive agent.

Alternatively, a metal film may be used as the bonding layer 5. In this case, bonding using the bonding layer 5 may be implemented by, for example, forming a metal film on the surface of the semiconductor substrate 1, patterning the metal film into a desired shape to form the bonding layer 5, and then bonding the bonding layer 5 to the light-transmissive plate 4. Such a configuration in which a metal film is used as the bonding layer 5 provides the bonding layer 5 with fine patternability, and is thus appropriate for an optical device in which the light-receiving elements 21a are arranged at narrow pitches. In addition, since the metal film transmits little light, the bonding layer 5 made of the metal film may be also used for blocking light. In the case where the metal film is used as the bonding layer 5, it is preferable that surface films (the insulating film 13 and the planarizing film 18) of the semiconductor substrate 1 be planarized. In this case, for example, first a Ti—Cu film is formed by vapor-depositing Ti on a surface of the semiconductor substrate 1 as a seed layer, plating the surface of the semiconductor substrate 1 with Cu, and planarizing the surface of the semiconductor substrate using a technique such as chemical mechanical polishing (CMP). Next, the Ti—Cu film is patterned into a desired shape, and then directly bonded, using a technique such as anodic bonding, to the light-transmissive plate 4 which is made of siliceous glass or has a surface film (for example, an optical filter film) made of siliceous glass. In the case where the metal film is bonded to a siliceous glass layer, it is preferable to form a cobalt metal film on the bonding interface of the metal film by vapor deposition in order to provide the metal film with a linear expansion coefficient which matches that of siliceous glass. This prevents interfacial peeling. Alternatively, the bonding layer 5 may be bonded to the light-transmissive plate 4 and the semiconductor substrate 1 via an appropriate adhesive agent.

In addition, in the case where surface films (the insulating film 13 and the planarizing film 18) of the semiconductor substrate 1 and the light-transmissive plate 4 are made of an organic material, it is preferable that the bonding layer 5 be made of an adhesive organic material. In this case, bonding is implemented by, for example, forming an film made of an organic material on the surface of the semiconductor substrate 1, precuring the film made of an organic material, patterning the organic material into a desired shape to form the bonding layer 5, and then curing the film made of an organic material with the light-transmissive plate 4 stacked on the bonding layer 5 to react residual monomer. In this manner, the semiconductor substrate 1 and the light-transmissive plate 4 are chemically bonded (polymerization) using the bonding layer 5 made of an organic material, and thus an optical device having high bonding strength in the interfaces is provided.

The bonding layer 5 may be made of composite materials. For example, the bonding layer 5 may be made of a main material and an interface material. Here, it is preferable that the interface material have a linear expansion coefficient which is close to that of the surface film of the semiconductor substrate 1 and that of the light-transmissive plate 4 or the surface film of the light-transmissive plate 4.

It is to be noted that a method of bonding using the bonding layer is not limited the methods described above. The bonding layer 5 may be configured or bonded in a various way, and an optimum configuration and an optimum method are selected according to a type of the solid-state imaging device and a pattern of the bonding layer 5.

For example, the bonding layer 5 and the light-transmissive plate 4 may be bonded together after the bonding layer 5 is formed on the semiconductor substrate 1. Alternatively, the bonding layer 5 and the semiconductor substrate 1 may be bonded together so as to a match pattern on the semiconductor substrate 1 after the bonding layer 5 is formed on the light-transmissive plate 4.

In addition, the bonding layer 5 may be formed as an independent substrate. In this case, an appropriate fabrication method and a sequence of steps are selected for bonding of the semiconductor substrate 1, the light-transmissive plate 4, and the bonding layer 5, and pattering of the bonding layer 5.

Alternatively, the bonding layer 5 may be a pattern formed by processing a surface of the insulating film such as the planarizing film 18 or a surface of the light-transmissive plate 4 to be in contact with the bonding layer 5.

In addition, the light-transmissive plate 4 and the semiconductor substrate 1 may be directly bonded by a technique such as a thermal compressing bonding in which an adhesive agent is not used. Alternatively, the light-transmissive plate 4 and the semiconductor substrate 1 may be bonded via an adhesive agent by applying the adhesive agent to the surface of the light-transmissive plate 4 or the semiconductor substrate 1, or by printing an adhesive agent on the surface of the bonding layer 5.

In addition, the surface of the light-transmissive plate 4 may be coated with a film which bonds to the bonding layer 5 well as necessary in order to increase the bondability between the bonding layer 5 and the light-transmissive plate 4. The coating film preferably also functions as an optical filter for antireflection or infrared cutting. Similarly, the surface of the semiconductor substrate 1 may be coated with a film which bonds to the bonding layer 5 well as necessary in order to increase the bondability between the bonding layer 5 and the semiconductor substrate 1. The coating film preferably also functions as an insulating film in the same manner as the planarizing film 18. The bondability between the bonding layer 5 and the semiconductor substrate 1 may be increased using the coating film made of a reflowing material. In addition, bondability between the bonding layer 5 and the semiconductor substrate 1 may be improved by planarizing the coating film by CMP or etchback as necessary.

In addition, it is preferable that the semiconductor substrate 1 and the light-transmissive plate 4 be bonded at a low pressure atmosphere. Lowering the pressure in the hollow region of the bonding layer 5 prevents peeling of the light-transmissive plate 4 due to heat expansion, and thus providing the solid-state imaging device with increased resistance against heat in the manufacturing processes and operation.

As described above, in the solid-state imaging device according to Embodiment 1, the bonding layer 5 which bonds the semiconductor substrate 1 and the light-transmissive plate 4 includes: a circumferential layer 5a formed in the surrounding region of the light-receiving unit 2a; and the one or more pillars 5b formed with desired intervals so that the bonding layer 5 has an opening at least in part of the light-receiving regions corresponding to the respective light-receiving elements 21a in the light-receiving unit 2a. A solid-state imaging device is thus provided in a configuration which allows miniaturization of the solid-state imaging device while maintaining bonding strength between the semiconductor substrate 1 and the light-transmissive plate 4, reducing possibility of warpage, maintaining yields with less influence of voids, and maintaining design flexibility with more options for a bonding material. As a result, the present invention provides a solid-state imaging device which is small and provides high productivity and improved performance with high reliability.

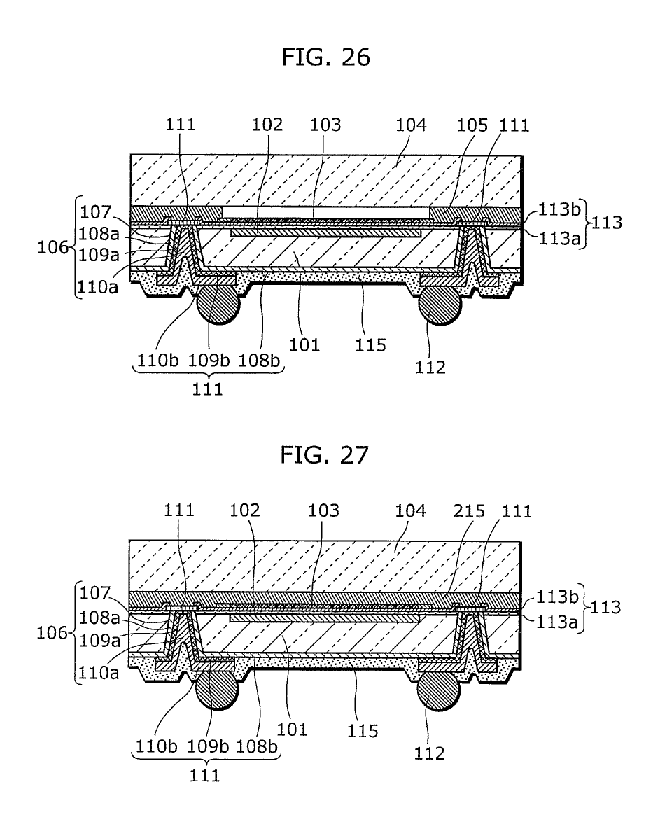

Specifically, bonding strength is secured with a structure in which the semiconductor substrate 1 and the light-transmissive plate 4 are bonded not only with the circumferential layer 5a formed in the surrounding region of the light-receiving unit 2a but also with the pillars 5b formed with desired intervals in the light-receiving unit 2a. A peripheral region necessary for the semiconductor substrate 1 to have comparable bonding strength (bonding region) is therefore smaller compared to the solid-state imaging device having a hollow structure shown in FIG. 26, and thus miniaturization of the solid-state imaging device is allowed. Thus, the solid-state imaging device according to Embodiment 1 is appropriate for a small-size optical device, such as a solid-state imaging device having the through electrode 6 and a back-side illumination solid-state imaging device having an electrode on its back side and a narrow surrounding region of the light-receiving unit 2a. On the other hand, in the case where the solid-state imaging device has a surrounding region comparable to that of the solid-state imaging device having a hollow structure shown in FIG. 26, the solid-state imaging device according to Embodiment 1 has higher bonding strength and is thus more resistant to impact. As a result, the solid-state imaging device according to Embodiment 1 is easy to handle and highly reliable, providing higher productivity.

In addition, the pillars 5b provided in the light-receiving unit 2a with desired intervals reduces influence of the hollow region in the bonding layer 5, and thus minimizes structural differences between the light-receiving unit 2a in which the light-receiving elements 21a are integrated and the surrounding region of the light-receiving unit 2a. As a result, possibility of warpage is reduced, and thus a solid-state imaging device having favorable device characteristics is provided. In addition, the pillars 5b minimize difference in polishing pressure at which the other surface of the semiconductor substrate 1 is polished in the thinning step, thereby reducing possibility of dishing. As a result, the configuration of the solid-state imaging device according to Embodiment 1 is appropriate for a method of manufacturing a solid-state imaging device in which the semiconductor substrate 1 is thinned after the large semiconductor substrate 1 and the large light-transmissive plate 4 are bonded together. The solid-state imaging device according to Embodiment 1 is therefore technically easy to manufacture, thus providing cost advantages.

In addition, the structure in which the bonding layer 5 has an opening above the light-receiving units 2a corresponding to the light-receiving element 21a reduces influence of a void in the bonding layer 5 on optical characteristics. Therefore, the configuration of the solid-state imaging device according to Embodiment 1 is appropriate for a method of manufacturing a solid-state imaging device in which a solid-state imaging device is produced by dicing an intermediate product prepared by bonding the large semiconductor substrate 1 and the large light-transmissive plate 4, and thus productivity is increased. In addition, since it is unnecessary to take into consideration influence of optical characteristics of the bonding layer 5, the flexibility in the choice of a bonding material is high. Therefore, the configuration of the solid-state imaging device according to Embodiment 1 is appropriate for a method of manufacturing a solid-state imaging device in which backend processes such as a thinning process and a wet process are performed after an intermediate product is prepared by bonding the large semiconductor substrate 1 and the large light-transmissive plate 4, and thus productivity is increased.

### Embodiment 2

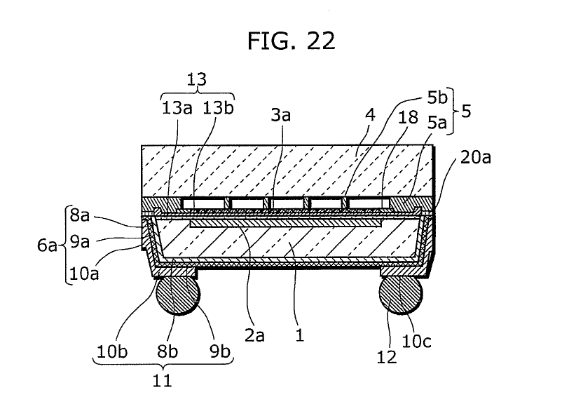

FIG. 22 is a sectional view illustrating a structure of a CMOS solid-state imaging device as an example of an optical device which has structure in which lateral electrodes are included according to Embodiment 2 of the present invention.

As shown in FIG. 22, the solid-state imaging device according to Embodiment 2 is a solid-state imaging device with lateral electrodes. In the solid-state imaging device, lateral electrodes 6a formed on a lateral surface of the semiconductor substrate 1 each electrically connect an electrode 20a and an external terminal 12. The electrode 20a is electrically connected with elements above one surface in which a light-receiving unit 2a of the semiconductor substrate 1 is formed. The external terminal 12 is provided on the other surface of the semiconductor substrate 1. Each of the lateral electrodes 6a include an insulating film 8a provided in contact with the lateral surface of the semiconductor substrate 1, a conducting film 9a provided in contact with the insulating film 8a, and a conductor 10a provide in contact with the conducting film 9a. The light-receiving elements in the light-receiving unit 2a are the optical elements formed on the top surface of the semiconductor substrate 1 and are covered with a light-transmissive plate 4 provided above the semiconductor substrate 1.

The semiconductor substrate 1 and the light-transmissive plate 4 are partially bonded to each other in a manner such that a space is formed between the semiconductor substrate 1 and the light-transmissive plate 4 and above the light-receiving unit 2a, which is an element region of the semiconductor substrate 1 and a region in which the light-receiving elements are formed. The bonding layer 5 is formed between the semiconductor substrate 1 and the light-transmissive plate 4 and bonds the semiconductor substrate 1 and the light-transmissive plate 4. The bonding layer 5 includes a circumferential layer 5a provided above a region surrounding the light-receiving unit 2a in the one surface of the semiconductor substrate 1, and pillars 5b provided above the light-receiving unit 2a and apart from the circumferential layer 5a. The pillars 5b are provided only in light-receiving regions, which are effective optical regions, of part of the light-receiving elements, and provided in positions outside the light-receiving regions of the rest of the light-receiving elements.

The lateral electrodes 6a provided in this manner eliminates the need for providing external electrodes above the one surface of the semiconductor substrate 1 in which the light-receiving unit 2a is formed and in the peripheral region of the semiconductor substrate 1, thus allowing miniaturization of the solid-state imaging device with a narrowed peripheral region thereof. In the structure of the solid-state imaging device according to Embodiment 2, bonding strength is secured by the bonding layer 5 including the pillars 5b. The structure is therefore appropriate for such a solid-state imaging device miniaturized with the lateral electrodes 6a.

In this manner, the solid-state imaging device according to Embodiment 2, which has the structure including the lateral electrodes, is thus miniaturized.

### Embodiment 3

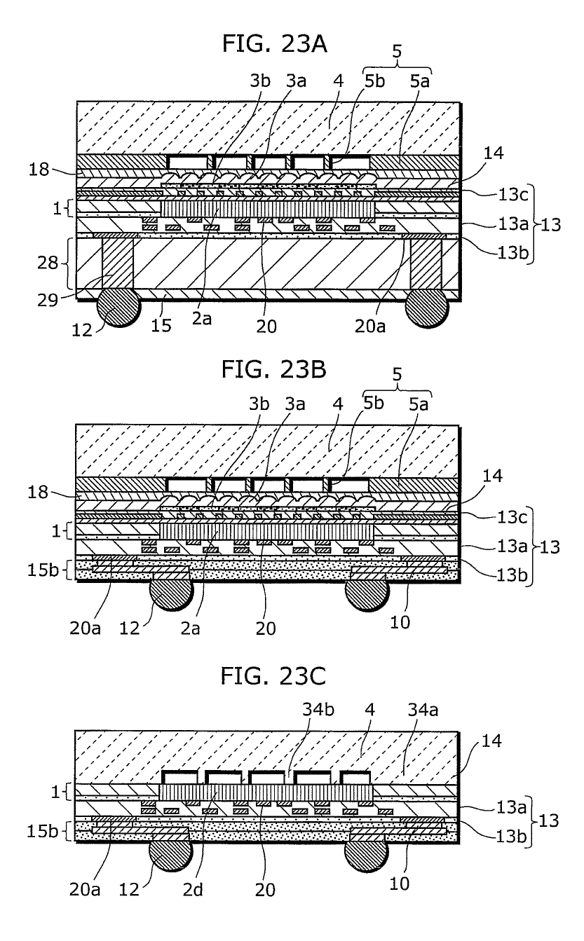

FIG. 23A is a sectional view illustrating a structure of a CMOS solid-state imaging device as an example of an optical device according to Embodiment 3 of the present invention.

As shown in FIG. 23A, the solid-state imaging device according to Embodiment 3 is a back-side illumination solid-state imaging device. In the solid-state imaging device, a semiconductor substrate 1 is formed to have a thin thickness, and elements and wiring 20 electrically connected to the elements are formed not on one surface (top surface) in which the light-receiving unit 2a is formed but on a side of the other surface (bottom surface) of the semiconductor substrate 1. An electrode 20a formed on one end of the wiring 20 is electrically connected to an external terminal 12 on the side of the bottom surface of the semiconductor substrate 1 by a through plug 29. On the top surface side of the semiconductor substrate 1, an insulating film 13c is formed. The light-receiving elements in the light-receiving unit 2a are the optical elements formed in the top surface of the semiconductor substrate 1 and are covered with the light-transmissive plate 4 provided above the semiconductor substrate 1. Each of the light-receiving elements of the light-receiving unit 2a has a light-receiving region, which is an effective optical region, above the top surface of the semiconductor substrate 1, and is electrically connected to the elements and the wiring 20 provided below the bottom surface of the semiconductor substrate 1

The semiconductor substrate 1 and the light-transmissive plate 4 are partially bonded to each other in a manner such that a space is formed between the semiconductor substrate 1 and the light-transmissive plate 4 and above the light-receiving unit 2a, which is an element region of the semiconductor substrate 1 and a region in which the light-receiving elements are formed. The bonding layer 5 is formed between the semiconductor substrate 1 and the light-transmissive plate 4 and bonds the semiconductor substrate 1 and the light-transmissive plate 4. The bonding layer 5 includes a circumferential layer 5a provided above a surrounding region of the light-receiving unit 2a in the top surface of the semiconductor substrate 1, and pillars 5b provided above the light-receiving unit 2a and apart from the circumferential layer 5a. The pillars 5b are provided only in light-receiving regions of part of the light-receiving elements, and provided in position outside the light-receiving regions of the rest of the light-receiving elements.

For such a back-side illumination solid-state imaging device, external electrodes need not be provided above the one surface of the semiconductor substrate 1 in which the light-receiving unit 2a is formed and in the peripheral region of the semiconductor substrate 1, thus allowing miniaturization of the solid-state imaging device with a narrowed peripheral region thereof. In the structure of the solid-state imaging device according to Embodiment 3, bonding strength is secured by the bonding layer 5 including the pillars 5b. The structure is therefore appropriate for such a back-side illumination solid-state imaging device with miniaturized a configuration as a back-side illumination type.

The following describes a method of manufacturing the solid-state imaging device according to Embodiment 3.

First, a surface (bottom surface) of the semiconductor substrate 1 provided with elements and wiring 20 is bonded to a support substrate 28. The surface is on the side where the wiring 20 is formed.

Next, the semiconductor substrate 1 is thinned so that the light-receiving unit 2a is exposed in the other surface of the semiconductor substrate 1.

Next, optical components such as a photo-shielding film 14, microlenses 3a, and color filters 3b are formed above the surface of the semiconductor substrate 1 in which the light-receiving unit 2a is exposed.

Next, the semiconductor substrate 1 is bonded to the light-transmissive plate 4 via the bonding layer 5.

Then, electrodes 20a and external terminals 12 are electrically connected via through plugs 29 formed in the support substrate 28.

The back-side illumination solid-state imaging device receives light from the surface opposite to the surface on the side where the elements are formed, through the semiconductor substrate 1 having a ultra-thin (approximately 5 to 15 micrometers). The support substrate 28 is provided in order to secure strength of the semiconductor substrate 1 having such a thin-thickness.

The solid-state imaging device according to Embodiment 3 may not include the support substrate 28 to have thin thickness. In the back-side illumination solid-state imaging device shown in FIG. 23B, the support substrate 28 is peeled to expose the electrode 20a on the surface after the light-transmissive plate 4 is bonded via the bonding layer 5. In the solid-state imaging device shown in FIG. 23B, a surface of the insulating film 13 is covered with a stress relieving layer (insulating film) 15b in order to protect the semiconductor substrate 1. The stress relieving layer 15b contains conductors 10 via which the external terminal 12 and the electrode 20a disposed with desired intervals are electrically connected. In the solid-state imaging device according to Embodiment 3, strength of the semiconductor substrate 1 is secured by a hollow structure including pillars 5b above the light-receiving unit 2a. The structure according to Embodiment 3 is therefore appropriate for the back-side illumination solid-state imaging device which does not have the support substrate 28.

In this manner, the solid-state imaging device according to Embodiment 3, which has the structure of a back-illumination type, is thus miniaturized.

### Embodiment 4

FIG. 23C is a sectional view illustrating a structure of a light-receiving and -emitting device as an example of an optical device according to Embodiment 4 of the present invention.

As shown in FIG. 23C, the light-receiving and -emitting device according to Embodiment 4 is a back-side illumination light-receiving and -emitting device. In the process of manufacturing the light-receiving and -emitting device, first one surface (top surface) of the semiconductor substrate 1 in which the light-receiving and -emitting part 2d is formed is bonded to the light-transmissive plate 4 via a bonding agent, and then the semiconductor substrate 1 is thinned and an element layer and wiring 20 is formed. In the light-receiving and -emitting part 2d, light-receiving elements and light-emitting elements are formed as optical elements. The light-receiving elements and the light-emitting elements formed in the top surface of the semiconductor substrate 1 are covered with a light-transmissive plate 4 provided above the semiconductor substrate 1.

The semiconductor substrate 1 and the light-transmissive plate 4 are partially bonded to each other in a manner such that a space is formed between the semiconductor substrate 1 and the light-transmissive plate 4 and above the light-receiving and -emitting part 2d, which is an element region of the semiconductor substrate 1 and a region in which the light-receiving elements and the light-emitting elements are formed. The light-transmissive plate 4 has a circumferential part 34a and pillar parts 34b on its surface. The circumferential part 34a is provided above a region surrounding the light-receiving and -emitting part 2a in the top surface of the semiconductor substrate 1. The pillar parts 34b are provided above the light-receiving and -emitting part 2d and apart from the circumferential part 34a. The pillar parts 34b are provided only in light-receiving regions, which are effective optical regions of part of the light-receiving elements, and light-emitting regions, which are an effective optical regions of part of the light-emitting elements, and provided in positions outside the light-receiving regions of the rest of the light-receiving elements and the light-emitting regions of the rest of the light-emitting elements.

The following describes a method of manufacturing the light-receiving and -emitting device according to Embodiment 4.

First, a surface of the light-transmissive plate 4 is micro-processed so that protrusions and recesses are formed in the surface of the light-transmissive plate 4.

Next, the surface of the light-transmissive plate 4 in which the protrusions and recesses are formed and one surface of the semiconductor substrate 1 in which the light-receiving and -emitting part 2d is formed are bonded in a manner such that the semiconductor substrate 1 is in contact with the light-transmissive plate 4 not in the recesses but on the protrusions in the surface thereof, and then the semiconductor substrate 1 is thinned.

Next, elements and wiring 20 are formed on the side of the other surface of the semiconductor substrate 1. It is to be noted that the configurations of bonding parts of the semiconductor substrate 1 and the light-transmissive plate 4 need to match the process of forming the elements and the wiring 20 after the bonding. It is therefore preferable that, for example, the light-transmissive plate 4 having the protrusions and recesses and the one surface of the semiconductor substrate 1 in which the light-receiving and -emitting part 2d is formed be directly bonded.

In the light-receiving and -emitting device according to Embodiment 4, strength of the semiconductor substrate 1 is secured by a hollow structure including the pillar parts 34b above the surface in which light-receiving and -emitting part 2b is formed. The structure according to Embodiment 4 is therefore appropriate for a method of manufacturing a back-side illumination light-receiving and -emitting device in which elements are formed in the semiconductor substrate 1 after the semiconductor substrate 1 and the light-transmissive plate 4 are bonded.

In this manner, the light-receiving and -emitting device according to Embodiment 4, which has the structure of a back-illumination type, is thus miniaturized.

Although the protrusions and recesses are formed in the surface of the light-transmissive plate 4, and the light-transmissive plate 4 includes the circumferential part 34a and the pillar parts 34b on its surface as describe above in Embodiment 4, such protrusions and recesses may be formed in the surface of the semiconductor substrate 1 on the side of the light-receiving and -emitting part, the semiconductor substrate 1 and the light-transmissive plate 4 are bonded in a manner such that the semiconductor substrate 1 is in contact with the light-transmissive plate 4 not in the recesses but on the protrusions, and the semiconductor substrate 1 may have the circumferential part 34a and the pillar part 34b on the surface thereof.

### Embodiment 5

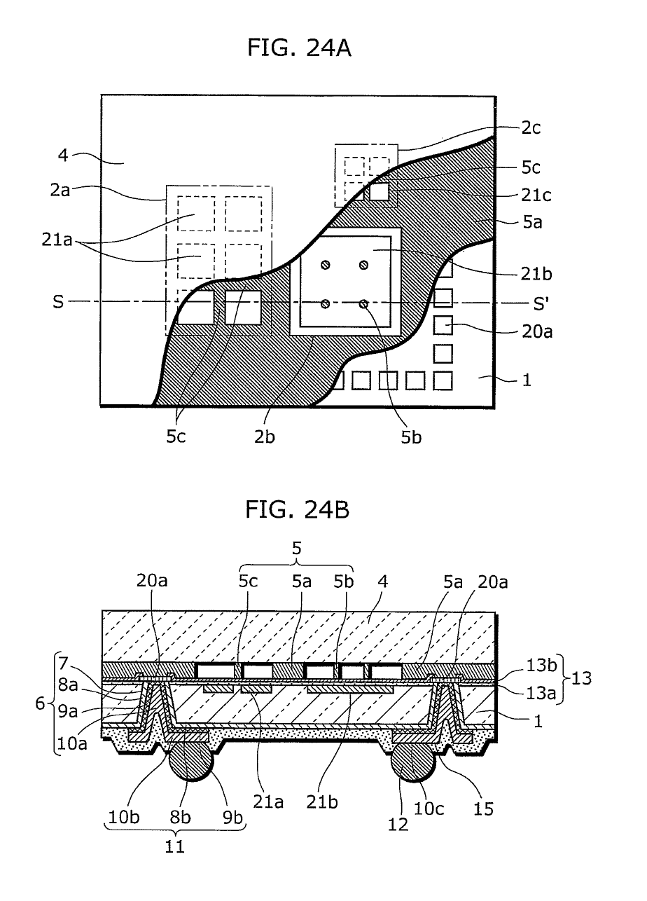

FIG. 24A is a schematic plan view illustrating a light-receiving and -emitting device viewed from the top as an example of an optical device according to Embodiment 5 of the present invention. FIG. 24B is a sectional view illustrating a structure of the light-receiving and -emitting device (a sectional view taken from the line S-S′ in FIG. 24A).

As shown in FIG. 24A and FIG. 24B, the light-receiving and -emitting device according to Embodiment 5 is a light-receiving and -emitting device with through electrodes. In the light-receiving and -emitting device, electrodes 20a, which are electrically connected to light-receiving elements 21 and 21b and light-emitting element 21c as optical elements formed in one surface of the semiconductor substrate 1, are electrically connected, via through electrodes 6 and rewiring 11, to an external terminals 12 formed below the other surface of the semiconductor substrate 1. In addition, the one surface of the semiconductor substrate 1 and the light-transmissive plate 4 are bonded via a bonding layer 5 in which openings are provided in light-receiving regions and a light-emitting region (effective optical regions) corresponding to the light-receiving elements 21a and 21b and the light-emitting element 21c, respectively. The light-receiving elements 21a and 21b and the light-emitting element 21c formed in the top surface of the semiconductor substrate 1 are covered with the light-transmissive plate 4 provided above the semiconductor substrate 1.

The semiconductor substrate 1 and the light-transmissive plate 4 are partially bonded to each other in a manner such that a space is formed between the semiconductor substrate 1 and the light-transmissive plate 4 and above the light-receiving units 2a and 2b and the light-emitting unit 2c, which are element regions of the semiconductor substrate 1 and a region in which the light-receiving elements 21a and 21b and the light-emitting element 21c are formed. The bonding layer 5 is formed between the semiconductor substrate 1 and the light-transmissive plate 4 and bonds the semiconductor substrate 1 and the light-transmissive plate 4. The bonding layer 5 includes a circumferential layer 5a provided above a region surrounding the light-receiving units 2a and 2b and the light-emitting unit 2c in the one surface of the semiconductor substrate 1, and pillars 5b and 5c provided above the light-receiving units 2a and 2c and the light-emitting unit 2c, respectively, and apart from the circumferential layer 5a.

In the light-receiving and -emitting device according to Embodiment 5, bonding strength is secured by the bonding layer 5 including circumferential layer 5a and pillars 5b and 5c. The structure according to Embodiment 5 is therefore appropriate for the light-receiving and -emitting device miniaturized with the through electrodes 6.

In the light-receiving and -emitting device according to Embodiment 5, the light-receiving unit 2a, the light-receiving unit 2b, and the light-emitting unit 2c are formed to correspond to an integrating part of the light-receiving elements 21a, light-receiving elements 21b having a relatively large light-receiving region, and an integrating part of the light-emitting element 21c, respectively. The circumferential layer 5a in the bonding layer 5 is formed above the one surface of the semiconductor substrate 1 except above the light-receiving units 2a and 2b and the light-emitting unit 2c. The pillars 5c in the bonding layer 5 are formed in the light-receiving unit 2a and the light-emitting unit 2c in which the light-receiving elements 21a and the light-emitting element 21c are integrated, respectively. The pillars 5c corresponding to the light-receiving units 2a and the light-emitting unit 2c are integrally formed in regions except light-receiving regions corresponding to the light-receiving element 21a and light-emitting region corresponding to the light-emitting element 21c, respectively, and connected to the circumferential layer 5a. There are one or more pillars 5b in the bonding layer 5 formed in the light-receiving region of the light-receiving elements 21b with desired intervals.

As described above, in the light-receiving and -emitting device according to Embodiment 5, the pillars 5c in the light-receiving elements 21a and the light-emitting element 21c are integrally formed to be mutually connected in the respective regions, and further integrated with the circumferential layer 5a. In this configuration, the pillars 5c are prevented from deformation, and thus providing a light-receiving and -emitting device with increased strength. Such a structure of the bonding layer 5 is appropriate for a light-receiving and -emitting device having relatively large spaces between the light-receiving and -emitting elements formed in the light-receiving and -emitting part.

In addition, in the light-receiving and -emitting device according to Embodiment 5, the pillars 5b are formed to cover part of the light-receiving regions of the light-receiving elements 21b. Such a structure of the bonding layer 5 is appropriate for a light-receiving and -emitting device including a light-receiving element having a relatively large light-receiving region.

### Embodiment 6

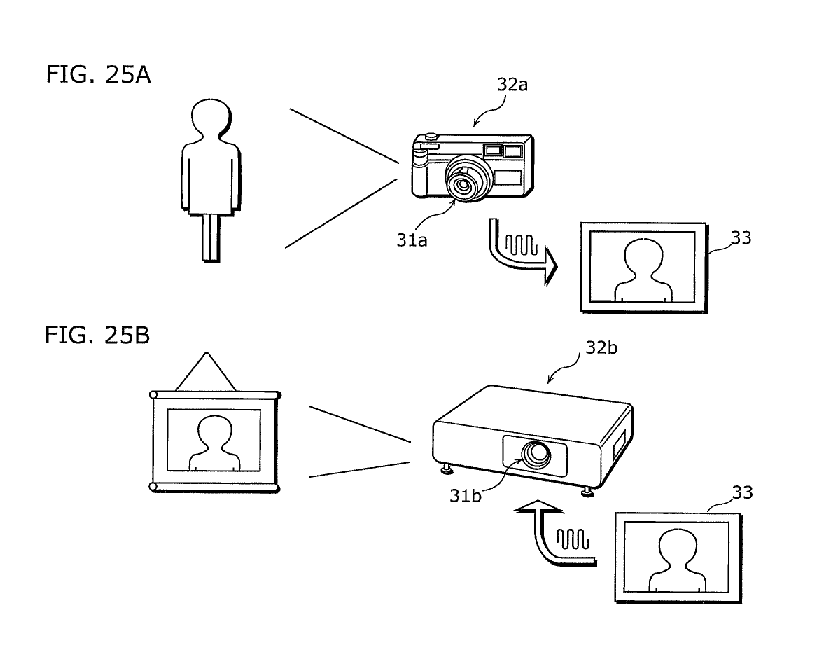

FIG. 25A and FIG. 25B schematically illustrates structures of optical apparatuses (optical modules) as examples of an electronic apparatus according to Embodiment 6 of the present invention.

In the optical apparatus according to Embodiment 6, an optical device according to any of Embodiments 1 to 5 is incorporated (installed) in desired wiring parts (not shown) with various optical parts as necessary.

FIG. 25A and FIG. 25B are schematic views illustrating optical systems including optical apparatuses according to Embodiment 6.

An optical apparatus 32a illustrated in FIG. 25A includes an optical unit 31a in which a solid-state imaging device is incorporated as an optical device, and converts information on incident light into electrical data 33 such as an picture through photoelectric conversion and signal processing. An optical apparatus 32b illustrated in FIG. 25B includes an optical unit 31b in which a display device (light-emitting device) is incorporated as an optical device, and performs signal processing and photoelectric conversion on electrical data 33 such as an picture to project it as light according to a signal.

The optical apparatuses according to Embodiment 6 are applicable to optical apparatuses including various optical devices such as a light-receiving device and a light-emitting device. For example, the light-receiving device is an imaging device or a photo IC, and the light-emitting device is a light-emitting diode (LED) or a laser device.

Although the optical devices, method of manufacturing the same, and optical apparatus including the same according to the present invention have been described according to the embodiments, the present invention is not limited to the embodiments. The present invention also includes variations of the present invention conceived by those skilled in the art unless they depart from the spirit and scope of the present invention. The present invention also includes a different embodiment where the components in the embodiments above are used in any combination unless they depart from the spirit and scope of the present invention.

For example, the light-receiving element in the above embodiment is an exemplary optical element of the present invention. When the optical device is a light-emitting device such as a display apparatus, the optical element is a light-emitting element such as a light-emitting diode or a light-emitting laser element.

In addition, although the solid-state imaging devices in the above embodiments are described as CMOS solid-state imaging devices, the solid-state imaging device may be various types of devices such as a charge-coupled device (CCD) solid-state imaging device.

In addition, although a solid-state imaging device including a through electrode, a solid-state imaging device including a lateral electrode, a back-side illumination solid-state imaging device, a back-side illumination light-receiving and -emitting device, and a light-receiving and -emitting device including a through electrode are described as optical devices in above embodiments, the present invention is not limited to them except in the most characteristics parts. That is, the optical device according to present invention may have any configuration in which the semiconductor substrate and the light-transmissive plate are bonded in the manner such that the optical device has a hollow structure above the light-receiving and -emitting part. In this case, the optical device has main components appropriated for optical elements therein.

### INDUSTRIAL APPLICABILITY

The present invention is applicable to optical devices, methods of manufacturing the same, and electronic apparatuses, and particularly to various optical devices and apparatuses over a wide range of uses regardless of consumer, industrial, and medical applications, which are typified by imaging apparatuses such as digital still cameras, digital camcorders, and camera-equipped mobile phones, display apparatuses such as monitors and projectors, optical drives and pointers, and optical sensors.

What is claimed is:

1. An optical device comprising:
a semiconductor substrate having one surface in which an optical element is formed; and
a light-transmissive plate provided above said semiconductor substrate so as to cover the optical element,
wherein said semiconductor substrate and said light-transmissive plate are partially bonded above an element region of said semiconductor substrate, the element region being a region in which the optical element is formed.

2. The optical device according to claim 1, comprising
a bonding layer formed between said semiconductor substrate and said light-transmissive plate to bond said semiconductor substrate and said light-transmissive plate,
wherein said bonding layer includes: a circumferential layer provided above a region surrounding the element region of said semiconductor substrate; and a pillar provided above the element region and apart from said circumferential layer.

3. The optical device according to claim 2,
wherein said pillar is provided in an effective optical region of the optical element.

4. The optical device according to claim 3,
wherein said pillar has a structure for blocking light in the effective optical region.

5. The optical device according to claim 2,
wherein said pillar is provided in a position outside the effective optical region of the optical element.

6. The optical device according to claim 2, further comprising
a planarizing film provided between said pillar and said semiconductor substrate.

7. The optical device according to claim 2, further comprising
an optical component provided above the one surface of said semiconductor substrate correspondingly to the optical element,
wherein the optical component is provided above a region of the one surface of said semiconductor substrate, the region being a region above which said pillar is not provided.

8. The optical device according to claim 2,
wherein a slit is formed in said circumferential layer.

9. The optical device according to claim 2, further comprising
a through electrode which penetrates said semiconductor substrate and electrically connects an electrode and an external terminal, the electrode being provided above the one surface of said semiconductor substrate and electrically connected to the optical element, and the external terminal being provided below an other surface of said semiconductor substrate.

10. The optical device according to claim 2,
wherein the optical element has an effective optical region in the one surface of said semiconductor substrate and is electrically connected to an element and wiring provided on an other surface of said semiconductor substrate.

11. An electronic apparatus in which the optical device according to claim 1 is incorporated.

12. A method of manufacturing an optical device, said method comprising:
forming optical elements in a semiconductor substrate in a manner such that the optical elements are arranged on both sides of a scribe region of the semiconductor substrate;
bonding the semiconductor substrate and a light-transmissive plate; and
dicing the semiconductor substrate in the scribe region,
wherein, in said bonding, the semiconductor substrate and the light-transmissive plate are partially bonded above an element region in which the optical elements in the semiconductor substrate are formed.

13. The method of manufacturing an optical device according to claim 12,
wherein, in said bonding, the semiconductor substrate and the light-transmissive plate are bonded via a bonding layer, and
the bonding layer includes: a circumferential layer provided above a region surrounding the element region of the semiconductor substrate; and a pillar provided above the element region and apart from the circumferential layer.

14. The method of manufacturing an optical device according to claim 13,
wherein, in said bonding, the bonding layer is formed above the semiconductor substrate, and then the bonding layer and the light-transmissive plate are bonded.

15. The method of manufacturing an optical device according to claim 12,
wherein a protrusion and a recess are formed in a surface of the semiconductor substrate, and
in said bonding, the semiconductor substrate and the light-transmissive plate are bonded so that the semiconductor substrate is in contact with the light-transmissive plate not in the recess but on the protrusion in the surface.

16. The method of manufacturing an optical device according to claim 13,
wherein, in said bonding, the bonding layer is formed above the light-transmissive plate, and then the bonding layer and the semiconductor substrate are bonded.

17. The method of manufacturing an optical device according to claim 12,
wherein a protrusion and a recess are formed in a surface of the light-transmissive plate, and
in said bonding, the semiconductor substrate and the light-transmissive plate are bonded so that the light-transmissive plate is in contact with the semiconductor substrate not in the recess but on the protrusion in the surface.

18. The method of manufacturing an optical device according to claim 13,
wherein the bonding layer is provided above a region of a surface of the semiconductor substrate, the region being a region other than the scribe region.

19. The method of manufacturing an optical device according to claim 13,
wherein the light-transmissive plate has a bonding part to the bonding layer and the bonding layer has a bonding part to the light-transmissive plate and materials for the respective bonding parts have similar physical properties so that light-transmissive plate and the bonding layer are chemically bonded to each other, or the semiconductor substrate has a bonding part to the bonding layer and the bonding layer has a bonding part to the semiconductor substrate and materials for the respective bonding parts have similar physical properties so that semiconductor substrate and the bonding layer are chemically bonded to each other.

20. The method of manufacturing an optical device according to claim 19,
wherein the bonding part includes a silicate glass material.

21. The method of manufacturing an optical device according to claim 19,
wherein the bonding part includes an organic material.

22. The method of manufacturing an optical device according to claim 19,
wherein an optical filter is formed on a surface of the light-transmissive plate.
